(19) United States
(12) Patent Application Publication
(10) Pub. No.: US 2018/0314099 A1
(43) Pub. Date: Nov. 1, 2018

(54) DISPLAY BOARD, DISPLAY DEVICE, AND METHOD OF PRODUCING DISPLAY BOARD

(71) Applicant: SHARP KABUSHIKI KAISHA, Sakai City, Osaka (JP)

(72) Inventors: TAKAO SAITOH, Sakai City (JP); YOHSUKE KANZAKI, Sakai City (JP); MAKOTO NAKAZAWA, Sakai City (JP); KAZUATSU ITO, Sakai City (JP); SEIJI KANEKO, Sakai City (JP)

(21) Appl. No.: 15/772,086

(22) PCT Filed: Nov. 1, 2016
(86) PCT No.: PCT/JP2016/082381

§ 371 Date: Apr. 29, 2018

(30) Foreign Application Priority Data
Nov. 6, 2015 (JP) 2015-218417

(51) Int. Cl. G02F 1/1345; G02F 1/1335; G02F 1/1368; G02F 1/1362; G02F 1/1333; G06F 3/041; H01L 27/12; G02F 1/1343

(52) U.S. Cl. CPC G02F 1/13452; G02F 1/133514; G02F 1/133512; G02F 1/1368; G02F 1/136286; G02F 1/133345; G02F 2001/133357; G06F 3/0412; H01L 27/124; G02F 1/134309; G02F 2201/121; G02F 2201/123; G02F 1/13338

(57) ABSTRACT

An array board includes a glass substrate, input terminals, a gate insulating film including a gate insulating film edge section, a first interlayer insulating film including a first interlayer insulating film edge section, a first planarization film, and terminal lines. At least parts of the gate insulating film edge section and the first interlayer insulating film edge section are angled relative to a plate surface of the glass substrate with an angle of slope equal to or smaller than 35°. The first planarization film includes a first planarization film edge section angled relative to the plate surface with an angle of slope smaller than the angle of slope of the gate insulating film edge section. The terminal lines are disposed to cross the gate insulating film edge section, the first interlayer insulating film edge section, and the first planarization film edge section and connected to the input terminals.

### TECHNICAL FIELD

The present invention relates to a display board, a display device, and a method of producing the display board.

### BACKGROUND ART

A liquid crystal panel disclosed in Patent Document 1 is known as an example of liquid crystal panels used in conventional liquid crystal display devices. The liquid crystal panel disclosed in Patent Document 1 includes an active component array board that includes an interlayer insulating film. The interlayer insulating film includes a protrusion at an interlayer insulating film edge between mounted terminals to reduce resist residues in a post-process even if the interlayer insulating film is formed with a large thickness.

### RELATED ART DOCUMENT

### Patent Document

Patent Document 1: Japanese Unexamined Patent Application Publication No. H11-24101

### Problem to be Solved by the Invention

In the active component array board disclosed in Patent Document 1, the mounted terminals formed from a metal film are disposed in a layer lower than the interlayer insulating film. If the mounted terminals are disposed in a layer upper than the interlayer insulating film to cross the interlayer insulating film edge, the following problem may occur. During etching of the metal film formed in the layer upper than the interlayer insulating film with a mask in patterning of the mounted terminals, a section of the metal film overlapping the interlayer insulating film edge is less likely to be removed through the etching. Residues may cause a short circuit between the adjacent mounted terminals.

### DISCLOSURE OF THE PRESENT INVENTION

The present invention was made in view of the above circumstances. An object is to improve reliability in short-circuit protection.

### Means for Solving the Problem

A display board according to the present invention includes a board, terminals, first insulating film, a second insulating film, and terminal lines. The board includes a display area in which an image can be displayed and a non-display area disposed outside the display area to surround the display area. The terminals are disposed in the non-display area. The first insulating film is disposed to cross a boundary between the display area and the non-display area and includes a first insulating film edge section disposed between the terminals and the display area. The first insulating film edge section is an edge section of the first insulating film and angled relative to a plate surface of the board with an angle of slope of at least a part of the first insulating film edge section equal to or smaller than 35°. The second insulating film is disposed in a layer upper than the first insulating film to cross the boundary between the display area and the non-display area. The second insulating film includes a second insulating film edge section disposed between the terminals and the display area. The second insulating film edge section is an edge section of the second insulating film and angled relative to the plate surface of the board with an angle of slope larger than the angle of slope of the first insulating film edge section. The terminal lines are disposed in a layer upper than the second insulating film at least in the non-display area. The terminal lines are formed from a metal film, disposed to cross the first insulating film edge section and the second insulating film edge section, and connected to the terminals.

As described above, the terminal lines connected to the terminals disposed in the non-display area are disposed in the layer upper than the second insulating film to cross the first insulating film edge section and the second insulating film edge section between the terminals and the display area. The angle of slope of the second insulating film edge section of the second insulating film relative to the plate surface of the board is larger than the angle of slope of the first insulating film edge section of the first insulating film. In production of the display board, the first insulating film is more likely to be patterned using the second insulating film as a mask. In the production of the display board, the metal film that forms the terminal lines is formed in the layer upper than the second insulating film to form the terminal lines through patterning. During etching of the formed metal film via a resist, a section of the metal film overlapping the first insulating film edge section having the larger angle of slope relative to the plate surface of the board is less likely to be removed through the etching. Namely, residues of the metal film may cause a short circuit between the adjacent terminal lines.

Because the angle of slope of at least a part of the first insulating film edge section of the first insulating film relative to the plate surface of the board is equal to or smaller than 35°, the section of the metal film that forms the terminal lines at least partially overlapping the first insulating film edge section is more likely to be removed through the etching during the patterning of the terminal lines. The residues of the metal film are less likely to be produced in between sections of the adjacent terminal lines at least partially overlapping the first insulating film edge section. Therefore, the adjacent terminal lines are less likely to be shorted.

Preferable embodiments of the present invention may have the following configurations.

(1) The second insulating film may include a first thickness portion and a second thickness portion with a thickness smaller than a thickness of the first thickness portion. The second thickness portion may be disposed closer to the terminals relative to the first thickness portion and include the second insulating film edge section. Because the thickness of the second thickness portion is smaller than the thickness of the first thickness portion, in comparison to a configuration in which the thickness of the second insulating film is equal to the thickness of the first thickness portion for an entire area, the angle of slope of the second insulating film edge section included in the second thickness portion relative to the plate surface of the board is smaller. By patterning the first insulating film using the second insulating film as a mask in the production of the display board, the angle of the first insulating film edge section relative to the plate surface of the board can be reduced. Therefore, the angle of slope of the first insulating film edge section can be easily maintained equal to or smaller than 35° and thus further higher reliability can be achieved in the short circuit protection between the adjacent terminal lines.

(2) The angle of slope of the first insulating film edge section of the first insulating film relative to the plate surface of the board may be equal to or smaller than 35° for entire area. Because the angle of slope of the first insulating film edge section of the first insulating film relative to the plate surface of the board may be equal to or smaller than 35° for the entire area of the first insulating film edge section, a section of the metal film that forms the terminal lines overlapping the entire area of the first insulating film edge section is more likely to be removed through the etching. The residues of the metal film are less likely to be produced between sections between the adjacent terminal lines overlapping the entire area of the first insulating film edge section. In comparison to the configuration in which only a part of the first insulating film edge section has the angle of slope relative to the plate surface of the board equal to or smaller than 35°, further higher reliability can be achieved in the short circuit protection between the adjacent terminal lines.

(3) The first insulation film may include a projection at the first insulating film edge section. The projection may be disposed between the adjacent terminal lines to project toward the terminals. At least the projection at the first insulating film edge section may be angled relative to the plate surface of the board with an angle of slope equal to or smaller than 35°. Because at least the projection at the first insulating film edge section may be angled relative to the plate surface of the board with an angle of slope equal to or smaller than 35°, a section of the metal film that forms the terminal lines overlapping at least the projection at the first insulating film edge section is more likely to be removed through the etching during the forming of the terminal lines through the patterning. Therefore, the adjacent terminal lines are less likely to be shorted. Furthermore, a creepage distance between the adjacent terminal lines at the first insulating film edge section is increased by dimensions of the projection. Therefore, even if the residues of the metal film that forms the terminal lines are produced around the first insulating film edge section, the adjacent terminal lines are less likely to be bridged by the residues of the metal film.

(4) The projection may have a dimension between a base of projection and a distal end defined such that a ratio calculated by dividing the dimension by a thickness of the second insulating film edge section is equal to or smaller than 0.2. If the ratio calculated by dividing the dimension of the projection by the thickness of the second insulating film edge section is over 0.2, the residues of the metal film that forms the terminal lines are more likely to be produced around the first insulating film edge section and the adjacent terminal lines are more likely to be shorted. If the ration is equal to or smaller than 0.2, the residues of the metal film that forms the terminal lines are less likely to be produced around the first insulating film edge section and thus the adjacent terminal lines are less likely to be shorted.

To solve the problem described earlier, a display device according to the present invention includes the display board described above and a common board opposed to the display board. According to the display device having such a configuration, the display board has the high reliability in the short-circuit protection and thus higher operation reliability can be achieved.

A method of producing a display board according to the present invention includes at least a first insulating film forming process, a second insulating film forming process, a second insulating film shaping process, a first insulating film shaping process, a metal film forming process, a resist forming process, and a terminal line forming process. The first insulating film forming process includes forming a first insulating film on a board including a display area in which an image can be displayed, a non-display area disposed outside the display area to surround the display area, and terminals disposed in the non-display area to cross a boundary between the display area and the non-display area. The second insulating film forming process includes forming a second insulating film in a layer upper than the first insulating film to cross the boundary between the display area and the non-display area. The second insulating film shaping process includes shaping the second insulating film such that a second insulating film edge section that is an edge section of the second insulating film is angled relative to a plate surface of the board between the terminals and the display area. The first insulating film shaping process includes etching the first insulating film via the second insulating film such that a first insulating film edge section that is an edge section of the first insulating film is angled relative to the plate surface of the board with an angle of slope of at least a part of the first insulating film edge section larger than the angle of slope of the second insulating film edge section and equal to or smaller than 35° between the terminals and the display area. The metal film forming process includes forming a metal film in a layer upper than the second insulating film to cross the boundary between the display area and the non-display area. The resist forming process includes forming a resist in a layer upper than the metal film. The terminal line forming process includes etching the metal film via the resist to form terminal lines such that the terminal lines are disposed to cross the first insulating film edge section and the second insulating film edge section and connected to the terminals.

In the first insulating film forming process, the first insulating film is formed on the board to cross the boundary between the display area and the non-display area. Then, in the second insulating film forming process, the second insulating film is formed in the layer upper than the first insulating film on the board to cross the boundary between the display area and the non-display area. In the second insulating film forming process, the second insulating film edge section is formed such that the second insulating film edge section is angled relative to the plate surface of the board between the terminals and the display area. In the first insulating film forming process that is performed afterward, the first insulating film is etched via the second insulating film. The first insulating film edge section of the first insulating film has the angle of slope relative to the plate surface of the board larger than that of the second insulating film edge section but at least a part of the first insulating film edge section has the angle of slope smaller than 35°. The metal film is formed in the layer upper than the second insulating film to cross the boundary between the display area and the non-display area in the metal film forming process. Then, the resist is formed in the layer upper than the metal film in the resist forming process. The metal film is etched via the resist in the terminal line forming process to form the terminal lines such that the terminal lines are disposed to cross the first insulating film edge section and the second insulating film edge section and connected to the terminals.

During the etching of the metal film via the resist to form the terminal liens from the metal film in the terminal line forming process, the section of the metal film overlapping the first insulating film edge section having the larger angle of slope relative to the plate surface of the board is less likely to be removed through the etching. If the section remains, the adjacent terminal lines may be shorted. Because at least a part of the first insulating film edge section is formed to have the angle of slope relative to the plate surface of the board equal to or smaller than 35° in the first insulating film shaping process, the section of the metal film overlapping at least the part of the first insulating film edge section is more likely to be removed through the etching during the forming of the terminal lines from the metal film in the terminal lines forming process. The residues of the metal film are less likely to be produced between the sections of the adjacent terminal lines overlapping at least the part of the first insulating film edge section. Therefore, the adjacent terminal lines are less likely to be shorted.

A preferable embodiment of the method of producing a display board according to the present invention may include the following features.

(1) The second insulating film forming process may include forming the second insulating film using a photosensitive material. The second insulating film shaping process may include at least an exposing step and a developing step. The exposing step may include exposing the second insulating film using a halftone mask or a grey tone mask including a transmissive area and a semitransmissive area as a photomask. The halftone mask or the grey tone mask may be positioned such that at least the semitransmissive area overlaps a section of the second insulating film at which the second insulating film edge section is to be formed. The developing step may include developing the second insulating film. In the second insulating film forming process, the second insulating film is formed using the photosensitive material. In the exposing step included in the second insulating film shaping process, the second insulating film is exposed using the halftone mask or the grey tone mask including the transmissive area and the semitransmissive area. The second insulating film is developed in the developing step afterward and the second insulating film including the second insulating film edge section is shaped. Because at least the semitransmissive area of the halftone mask of the grey tone mask used in the exposing step is disposed to overlap the section of the second insulating film at which the second insulating film edge section is to be formed, the thickness of the section of the exposed and developed second insulating film including the second insulating film edge section becomes smaller than the thickness of other sections. When the first insulating film is etched via the second insulating film in the first insulating film shaping process, the angle of slope of the first insulating film edge section relative to the plate surface of the board becomes further smaller. Therefore, the angle of slope of the first insulating film edge section can be easily maintained equal to or smaller than 35° and thus further higher reliability can be achieved in the short circuit protection between the adjacent terminal lines.

### Advantageous Effect of the Invention

According to the present invention, reliability in short-circuit protection can be improved.

### BRIEF DESCRIPTION OF THE DRAWINGS

FIG. 1 is a plan view of a liquid crystal panel included in a liquid crystal display device according to a first embodiment of the present invention.

FIG. 2 is a plan view illustrating two-dimensional arrangement of a common electrode on an array board included in the liquid crystal panel.

FIG. 3 is a schematic cross-sectional view illustrating a cross-sectional configuration of the liquid crystal panel in a display area.

FIG. 4 is a plan view schematically illustrating a wiring configuration in a display area of an array board included in the liquid crystal panel.

FIG. 5 is a plan view schematically illustrating a wiring configuration in a display area of a CF board included in the liquid crystal panel.

FIG. 6 is a cross-sectional view along line vi-vi in FIG. 4.

FIG. 7 is a cross-sectional view along line vii-vii in FIG. 4.

FIG. 8 is a plan view schematically illustrating a wiring configuration in a non-display area of the array board included in the liquid crystal panel.

FIG. 9 is a cross-sectional view along line ix-ix FIG. 8.

FIG. 10 is a cross-sectional view along line x-x in FIG. 8.

FIG. 11 is a table illustrating a relation between angle of slope of a gate insulating film edge section and a first interlayer insulating film edge section and presence of residues of a third metal film according to comparative experiment 1.

FIG. 12 is a cross-sectional view along line ix-ix in FIG. 8 for illustrating an exposing step for exposing a first planarization film with a gray tone mask in production of the array board included in the liquid crystal panel.

FIG. 13 is a cross-sectional view along line ix-ix in FIG. 8 for illustrating a gate insulating film and first interlayer insulating film forming process for etching the gate insulating film and the first interlayer insulating film with the first planarization film that is developed in a developing step in the production of the array board included in the liquid crystal panel.

FIG. 14 is a cross-sectional view along line ix-ix in FIG. 8 illustrating the gate insulating film and the first interlayer insulating film formed through patterning in the gate insulating film and first interlayer insulating film forming process in the production of the array board included in the liquid crystal panel.

FIG. 15 is a cross-sectional view along line ix-ix in FIG. 8 illustrating a third metal film forming process for forming the third metal film in the production of the array board included in the liquid crystal panel.

FIG. 16 is a cross-sectional view along line x-x in FIG. 8 illustrating the third metal film forming process for forming the third metal film in the production of the array board included in the liquid crystal panel.

FIG. 17 is a cross-sectional view along line ix-ix in FIG. 8 illustrating an etching process for etching the third metal film with a photoresist that is formed through patterning in a resist forming process in the production of the array board included in the liquid crystal panel.

FIG. 18 is a cross-sectional view along line x-x in FIG. 8 illustrating the etching process for etching the third metal film with the photoresist that is formed through patterning in the resist forming process in the production of the array board included in the liquid crystal panel.

FIG. 19 is a cross-sectional view along line ix-ix in FIG. 8 illustrating terminal lines that are formed through the patterning in the etching process in the production of the array board included in the liquid crystal panel.

FIG. 20 is a cross-sectional view along line x-x in FIG. 8 illustrating the terminal lines that are formed through the patterning in the etching process in the production of the array board included in the liquid crystal panel.

FIG. 21 is a magnified plan view schematically illustrating a wiring configuration on an array board in a non-display area in a liquid crystal panel according to a second embodiment of the present invention.

FIG. 22 is a cross-sectional view along line xxii-xxii in FIG. 21.

FIG. 23 is a cross-sectional view along line xxiii-xxiii in FIG. 21.

FIG. 24 is a cross-sectional view along line xxiv-xxiv in FIG. 21.

FIG. 25 is a table illustrating a relation between ratio of a protruding dimension of a protrusion to a thickness of a first planarization film and presence of residues of a third metal film according to comparative experiment 2.

FIG. 26 is a magnified plan view schematically illustrating a wiring configuration on an array board in a non-display area in a liquid crystal panel according to a third embodiment of the present invention.

FIG. 27 is a cross-sectional view along line xxvii-xxvii in FIG. 26.

FIG. 28 is a cross-sectional view along line xxviii-xxviii in FIG. 26.

FIG. 29 is a cross-sectional view illustrating an exposing step for exposing a first planarization film with halftone mask in production of an array board included in a liquid crystal panel according to a fourth embodiment of the present invention.

### MODE FOR CARRYING OUT THE INVENTION

### First Embodiment

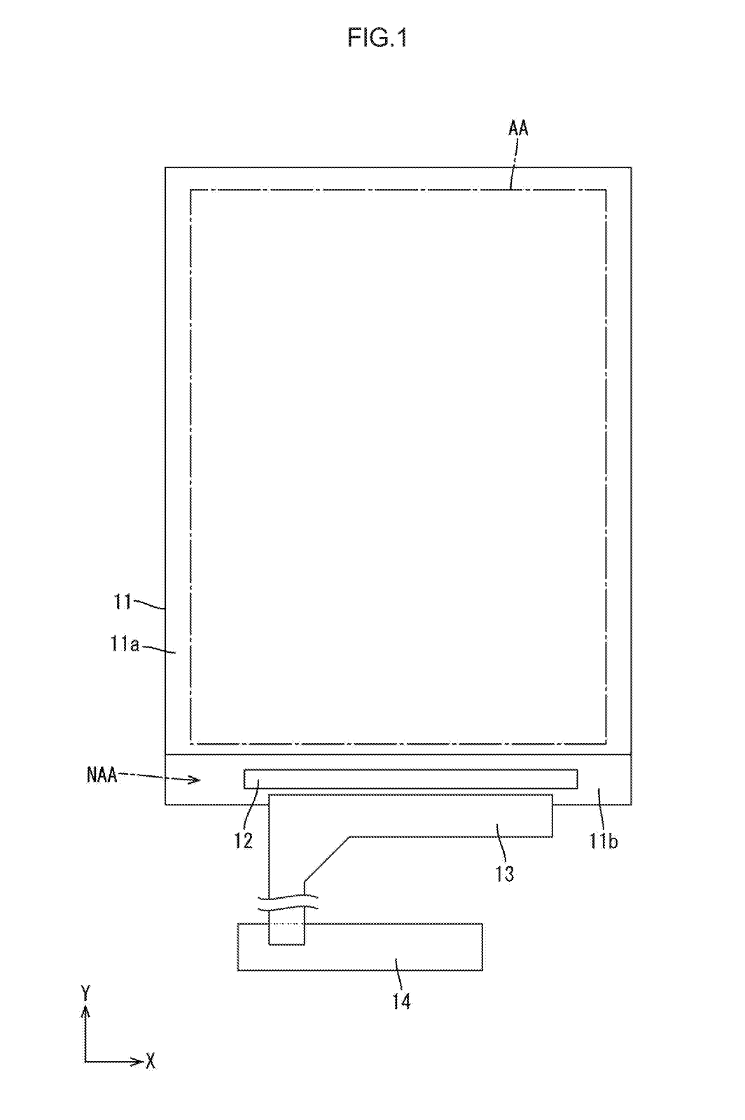

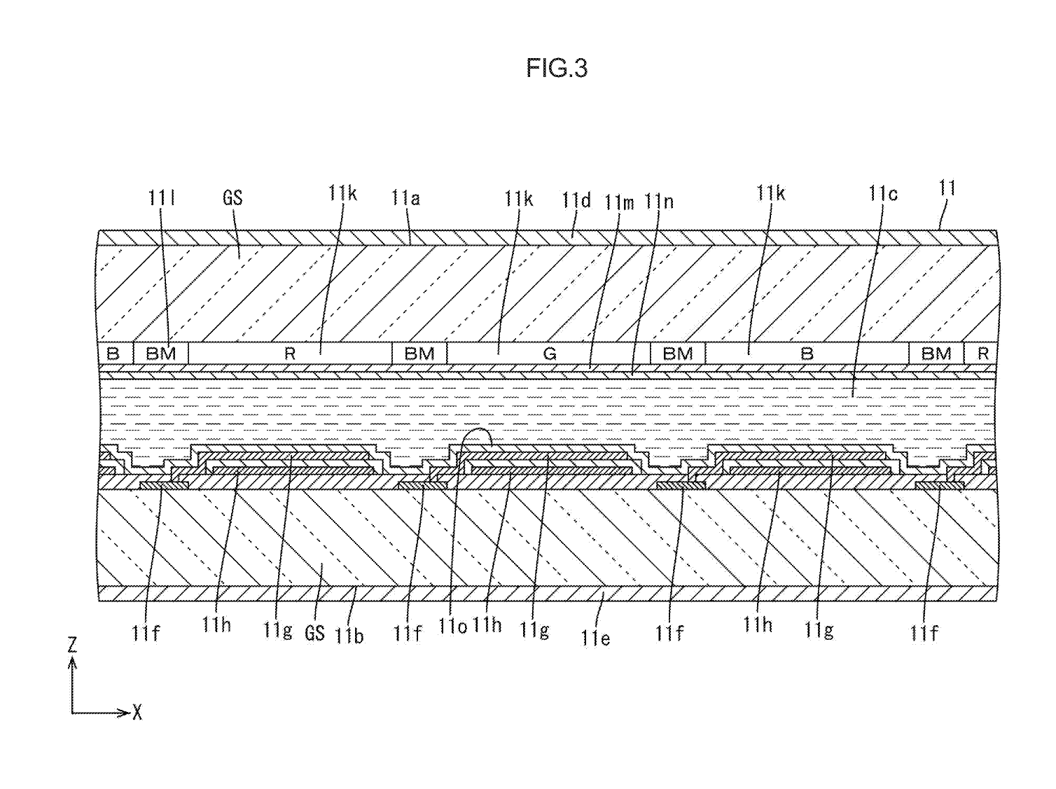

A first embodiment of the present invention will be described with reference to FIGS. 1 to 20. In this section, a liquid crystal panel 11 (a display device, a display panel) included in a liquid crystal display device 10 with a position input function will be described. X-axes, Y-axes, and Z-axes may be present in drawings. The axes in each drawing correspond to the respective axes in other drawings to indicate the respective directions. Upper sides and lower sides in FIGS. 3, 6 and 7 correspond to a front side and a rear side of the liquid crystal panel 11, respectively.

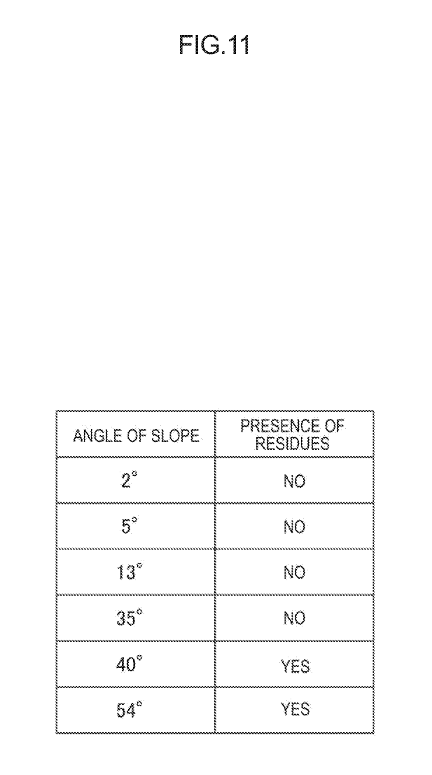

The liquid crystal display device 10 has a rectangular overall shape. As illustrated in FIG. 11, the liquid crystal display device 10 includes at least the liquid crystal panel 11 and a backlight unit (a lighting device). The liquid crystal panel 11 is configured to display images. The backlight unit is an external light source disposed behind the liquid crystal panel 11 and configured to apply light to the liquid crystal panel 11 for displaying images. Among components of the liquid crystal display device 10, the liquid crystal panel 11 will be described in detail but other components including the backlight unit will not be described in detail because they are well known.

As illustrated in FIG. 1, the liquid crystal panel 11 has a vertically-long rectangular overall shape. At a position closer to a first end of the liquid crystal panel 11 with respect to a long direction of the liquid crystal panel 11 (the upper side in FIG. 1), a display area AA (an active area) in which images are displayed is provided. A driver 12 and a flexible circuit board 13 for supplying various signals are mounted at positions closer to a second end of the liquid crystal panel 11 with respect to the long direction of the liquid crystal panel 11 (the lower side in FIG. 1). In the liquid crystal panel 11, the area outside the display area AA is the non-display area NAA (a non-active area) in which images are not displayed. The non-display area NAA includes a frame-shaped area that surrounds the display area AA (a frame-shaped section of a CF board 11a, which will be described later) and an area that is provided at the second end with respect to the long direction (a section of an array board 11b which is exposed without overlapping the CF board 11a, which will be described later). The area provided at the second end with respect to the long direction includes amounting area (an attachment area) in which the driver 12 and the flexible circuit board 13 are mounted. The short direction of the liquid crystal panel 11 corresponds with the X-axis direction and the long direction of the liquid crystal panel 11 corresponds with the Y-axis direction. Furthermore, the normal direction to the plate surface (the display surface) corresponds with the Z-axis direction. A control circuit board 14 (a control circuit board) which is a signal source is connected to an end of the flexible circuit board 13 on an opposite side from the liquid crystal panel 11 side. In FIG. 1, a chain line in a frame shape indicates an outline of the display area AA and an area outside the chain line is the non-display area NAA.

Components mounted or connected to the liquid crystal panel 11 (the driver 12, the flexible circuit board 13, and the control circuit board 14) will be described. As illustrated in FIG. 1, the driver 12 is an LSI chip including drive circuits. The driver 12 is configured to operate according to signals supplied by the control circuit board 14 to process the input signal supplied by the control circuit board 14, to generate output signals, and to output the output signals to the display area AA in the liquid crystal panel 11. The driver 12 has a vertically-long rectangular shape (an elongated shape that extends along the short side of the liquid crystal panel 11) in a plan view. The driver 12 is directly mounted in the non-display area NAA of the liquid crystal panel 11 (or the array board 11b, which will be described later), that is, mounted by the chip-on-glass (COG) mounting method. A long-side direction and a short-side direction of the driver 12 correspond to the X-axis direction (the short-side direction of the liquid crystal panel 11) and the Y-axis direction (the long-side direction of the liquid crystal panel 11), respectively.

As illustrated in FIG. 1, the flexible circuit board 13 includes a base member made of synthetic resin having insulating property and flexibility (e.g., polyimide resin). A number of traces are formed on the base member (not illustrated). As illustrated in FIG. 1, a first end of the long dimension of the flexible circuit board 13 is connected to the control circuit board 14 as described above. A second end of the long dimension of the flexible circuit board 13 is connected to the liquid crystal panel 11 (the array board 11b, which will be described later). In the liquid crystal display device 10, the flexible circuit board 13 is folded back such that a cross-sectional shape thereof forms a U-like shape. At the ends of the long dimension of the flexible circuit board 13, sections of the traces are exposed to the outside and configured as terminals (not illustrated). The terminals are electrically connected to the control circuit board 14 and the liquid crystal panel 11. With this configuration, signals supplied by the control circuit board 14 are transmitted to the liquid crystal panel 11.

As illustrated in FIG. 1, the control circuit board 14 is disposed on the back side of the backlight unit. The control circuit board 14 includes a substrate made of paper phenol or glass epoxy resin and electronic components mounted on the substrate and configured to supply various signals to the driver 12. Traces (conductive paths) which are not illustrated are formed in predetermined patterns. The first end of the flexible circuit board 13 is electrically and mechanically connected to the control circuit board 14 via an anisotropic conductive film (ACF), which is not illustrated.

The liquid crystal panel 11 will be described. As illustrated in FIG. 3, the liquid crystal panel 11 includes a pair of boards 11a and 11b and a liquid crystal layer 11c (a medium layer) in a space between the boards 11a and 11b. The liquid crystal layer 11c includes liquid crystal molecules having optical characteristics that vary according to application of electric field. The liquid crystal layer 11c is surrounded and sealed by a sealing agent disposed between the boards 11a and 11b. The sealing agent is not illustrated. One of the boards 11a and 11b on the front is the CF board 11a (a common board) and one on the rear (on the back) is the array board 11b (a display board, an active matrix board, a component board). The CF board 11a and the array board 11b include glass substrates GS and various films that are formed in layers on inner surfaces of the glass substrates GS. Polarizing plates 11d and 11e are attached to outer surfaces of the boards 11a and 11b, respectively.

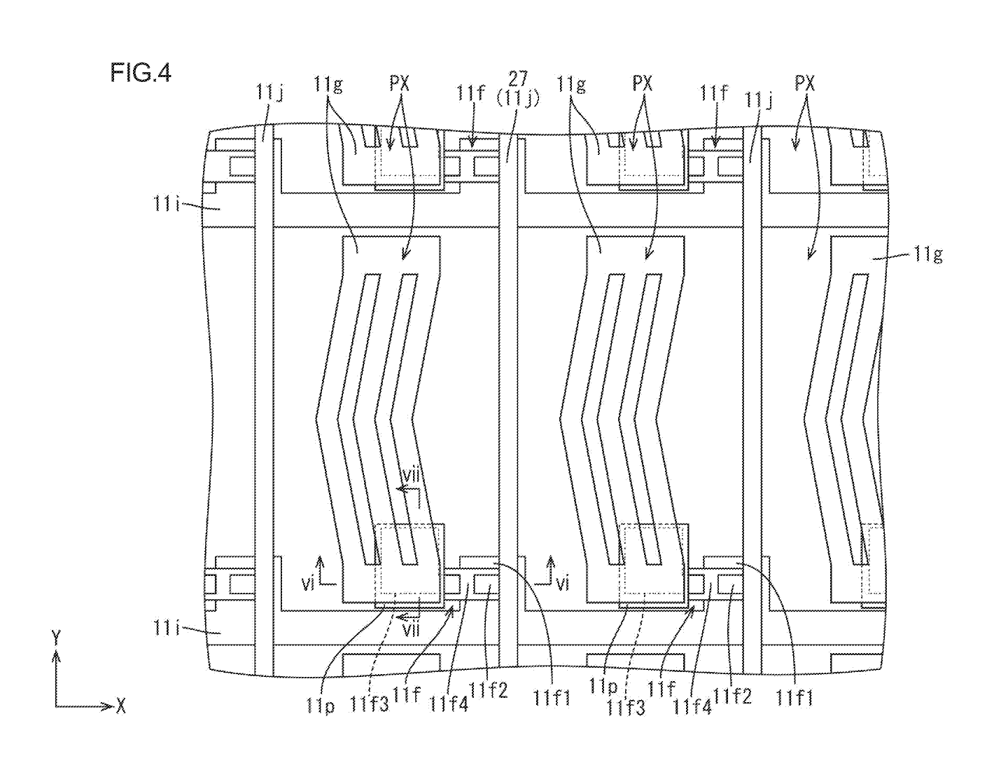

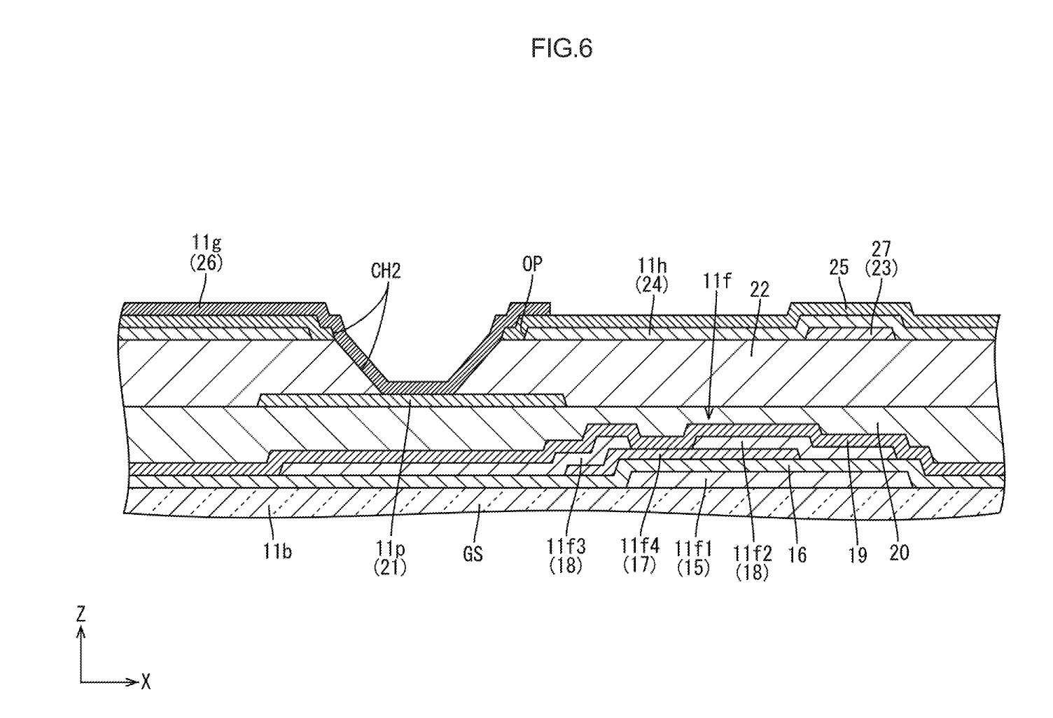

On an inner surface of the array board 11b (on the liquid crystal layer 11c side in the display area AA, an opposed surface opposed to the CF board 11a), as illustrated in FIGS. 4 and 6, thin film transistors 11f (TFTs, display components) which are switching components and pixel electrodes 11g are arranged in a matrix. Gate lines 11i (scan lines) and source lines 11j (data lines, signal lines, component lines) are routed in a grid to surround the TFTs 11f and the pixel electrodes 11g. The gate lines 11i and the source lines 11j are connected to gate electrodes 11f1 and source electrodes 11f2 of the TFTs 11f, respectively. The pixel electrodes 11g are connected to drain electrodes 11f3 of the TFTs 11f. The TFTs 11f are driven based on signals supplied to the gate lines 11i and the source lines 11j. Voltages are applied to the pixel electrodes 11g in accordance with the driving of the TFTs 11f. The TFTs 11f include channels 11f4 that connect the drain electrodes 11f3 to the source electrodes 11f2. In this embodiment, a direction in which the gate lines 11i extend and a direction in which the source lines 11j extend correspond with the X-axis direction and the Y-axis direction in each drawing, respectively. The pixel electrodes 11g are disposed in quadrilateral areas defined by the gate lines 11i and the source lines 11j. Each pixel electrode 11g includes slits. The pixel electrodes 11g area connected to the drain electrodes 11f3 of the respective TFTs 11f via the TFT connecting portions 11p (component connecting portions). A common electrode 11h is disposed on the inner surface of the array board 11b in addition to the pixel electrodes 11g. When a potential difference is created between the electrodes 11g and 11h, a fringe electric field (an oblique electric field) including a component along the plate surface of the array board 11b and a component in the normal direction to the plate surface of the array board 11b. The liquid crystal panel 11 operates in fringe field switching (FFS) mode that is an improved version of in-plane switching (IPS) mode.

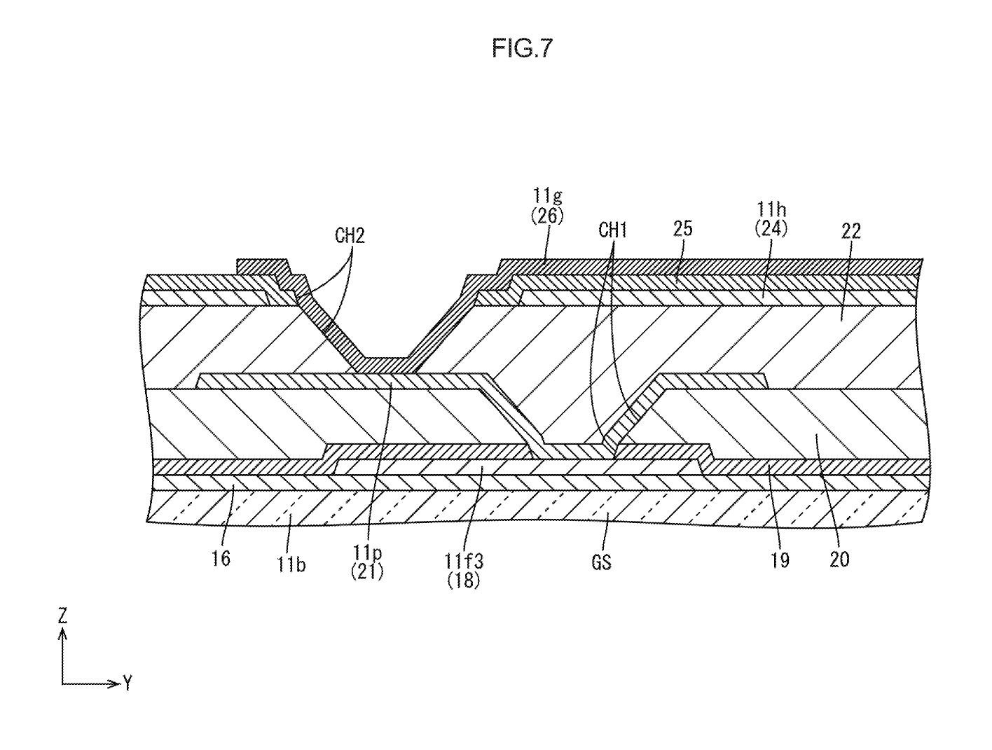

Various films are formed in layers on an inner surface of the array board 11b by the known photolithography method. The films will be described. As illustrated in FIGS. 6 and 7, on the array board 11b, a first metal film 15 (a gate metal film), a gate insulating film 16 (a lower layer-side first insulating film, a first insulating film), a semiconductor film 17, a second metal film 18 (a source metal film), a first interlayer insulating film 19 (an upper layer-side first insulating film, a first insulating film), a first planarization film 20 (a second insulating film), a third metal film 21 (a component connecting metal film, a metal film), a second planarization film 22, a fourth metal film 23 (a position detecting line metal film), a first transparent electrode film 24 (a lower layer-side transparent electrode film), a second interlayer insulating film 25, and a second transparent electrode film 26 (an upper layer-side transparent electrode film) are layered in this sequence from a lower layer side (a glass substrate GS). An alignment film 11o disposed in a layer upper than the second transparent electrode film 26 is not illustrated in FIGS. 6 and 7.

The first metal film 15 is a laminated film that includes three layers: a titanium (Ti) layer; an aluminum (Al) layer; and a titanium layer. The gate lines 11i are formed from the first metal film 15. As illustrated in FIGS. 6 and 7, the gate insulating film 16 is disposed in a layer at least upper than the first metal film 15. The gate insulating film 16 may be made of inorganic material such as silicon oxide (SiO2). The gate insulating film 16 is disposed between the first metal film 15 (the gate lines 11i) and the second metal film 18 (the source lines 11j) that are insulated from each other by the gate insulating film 16. The semiconductor film 17 is disposed in a layer upper than the gate insulating film 16. The semiconductor film 17 is a thin film made of substantially transparent oxide semiconductor. An oxide semiconductor of the semiconductor film 17 may be an In—Ga—Zn—O based semiconductor (indium gallium zinc oxide) containing indium (In), gallium (Ga), zinc (Zn), and oxygen (O). The In—Ga—Zn—O based semiconductor is a ternary oxide containing indium (In), gallium (Ga), and zinc (Zn). The ratio (the compound ratio) of indium to gallium and zinc is not limited to a specific ratio. Examples of the ratio include: In:Ga:Zn=2:2:1, In:Ga:Zn=1:1:1, In:Ga:Zn=1:1:2. In this embodiment, the ratio of Indium to gallium and zinc in the In—Ga—Zn—O based semiconductor is 1:1:1. The oxide semiconductor (the In—Ga—Zn—O based semiconductor) may have amorphous properties but preferably have crystalline properties, that is, including crystalline substances. A preferable oxide semiconductor having crystalline properties may be a crystalline In—Ga—Zn—O based semiconductor with the c-axis is substantially perpendicular to a layer surface. An example of crystalline structures of such an oxide semiconductor (the In—Ga—Zn—O based semiconductor) is disclosed in Japanese Unexamined Patent Application Publication No. 2012-134475. Whole disclosure of Japanese Unexamined Patent Application Publication No. 2012-134475 is incorporated by reference.

As illustrated in FIGS. 6 and 7, the second metal film 18 is disposed in a layer upper than at least the semiconductor film 17. The second metal film 18 is a laminated film that includes three layers: a titanium layer; an aluminum layer; and a titanium layer, similar to the first metal film 15. The source lines 11j, the source electrodes 11f2, and the drain electrodes 11f3 are formed from the second metal film 18. The first interlayer insulating film 19 is disposed in a layer upper than at least the second metal film 18. The first interlayer insulating film 19 is made of inorganic material such as silicon oxide (SiO₂). The first planarization film 20 is disposed in a layer upper than the first interlayer insulating film 19. The first planarization film 20 is made of acrylic resin material that is an organic material (e.g., polymethylmethacrylate resin (PMMA)). The first interlayer insulating film 19 and the first planarization film 20 are disposed in a layer between the third metal film 21 and the second metal film 18 and the semiconductor film 17 that are insulated from each other by the first interlayer insulating film 19 and the first planarization film 20. The third metal film 21 is disposed in a layer upper than at least the first planarization film 20. The third metal film 21 is a laminated film that includes three layers: a titanium layer; an aluminum layer; and a titanium layer, similar to the first metal film 15 and the second metal film 18. The TFT connecting portions 11p in the display area AA and input terminals 28 and terminal lines 29 in the non-display area NAA, which will be described later, are formed from the third metal film 21.

As illustrated in FIGS. 6 and 7, the second planarization film 22 is disposed in a layer upper than the third metal film 21 and the first planarization film 20. The second planarization film 22 is made of acrylic resin material that is an organic material (e.g., polymethylmethacrylate resin (PMMA)) similar to the first planarization film 20. The second planarization film 22 is disposed in the layer between the third metal film 21 and the fourth metal film 23 and the first transparent electrode film 24 that are insulated from each other by the second planarization film 22. The fourth metal film 23 is disposed in a layer upper than at least the second planarization film 22. The third metal film 21 is a laminated film that includes three layers: a titanium layer; an aluminum layer; and a titanium layer, similar to the first metal film 15, the second metal film 18, and the third metal film 21. The position detection lines 11q, which will be described later, are formed from the fourth metal film 23. The first transparent electrode film 24 is disposed in a layer upper than the fourth metal film 23 and the first planarization film 20. The first transparent electrode film 24 is made of transparent electrode material such as indium tin oxide (ITO) and zinc oxide (ZnO). The common electrode 11h in the display area AA and protective members 30 in the non-display area NAA, which will be described later, are formed from the first transparent electrode film 24. The second interlayer insulating film 25 is disposed in a layer upper than at least first transparent electrode film 24. The second interlayer insulating film 25 is made of inorganic material such as silicon nitride (SiNx). The second interlayer insulating film 25 is disposed in the layer between the first transparent electrode film 24 and the second transparent electrode film 26 that are insulated from each other by the second interlayer insulating film 25. The second transparent electrode film 26 is disposed in a layer upper than the second interlayer insulating film 25. The second transparent electrode film 26 is made of transparent electrode material such as indium tin oxide (ITO) and zinc oxide (ZnO) similar to the first transparent electrode film 24. The pixel electrodes 11g are formed from the second transparent electrode film 26. Among the insulating films 16, 19, 20, 22, and 25 described above, the first planarization film 20 and the second planarization film 22 are the organic insulating films having thicknesses larger than those of the other insulating films (inorganic insulating films) 16, 19, and 25. The first planarization film 20 and the second planarization film 22 have functions of planarizing surfaces. Among the insulating films 16, 19, 20, 22, and 25 described above, the gate insulating film 16, the first interlayer insulating film 19, and the second interlayer insulating film 25 other than the first planarization film 20 and the second planarization film 22 are the inorganic insulating films having thicknesses smaller than those of the organic insulating films, that is, the first planarization film 20 and the second planarization film 22.

As illustrated in FIG. 4, each TFT connecting portion 11p (the component connecting portion) has a vertically-long rectangular shape. The TFT connecting portions 11p are two-dimensionally arranged to overlap the drain electrodes 11f3 of the corresponding TFTs 11f and the corresponding pixel electrodes 11g in a plan view. As illustrated in FIG. 7, the first interlayer insulating film 19 and the first planarization film 20 include first TFT contact holes CH1 (first component contact holes) in areas that overlap the first TFT connecting portions 11p and the drain electrodes 11f3. The TFT connecting portions 11p in the upper layer are connected to the drain electrodes 11f3 in the lower layer through the first TFT contact holes CH1. As illustrated in FIG. 6, the second planarization film 22 and the second interlayer insulating film 25 include second TFT contact holes CH2 (second component contact holes, component contact holes) in areas that overlap the TFT connecting portions 11p and the drain electrodes 11f3 but not overlap the first TFT contact holes CH1. The pixel electrodes 11g in the upper layer are connected to the TFT connecting portions 11p in the lower layer through the second TFT contact holes CH2. Although four insulating films 19, 20, 22, and 25 are disposed between the pixel electrodes 11g and the drain electrodes 11f3, the pixel electrodes 11g and the drain electrodes 11f3 are connected to each other via the TFT connecting portions 11p disposed therebetween. Sections of the common electrode 11h overlapping the second TFT contact holes CH2 (sections of the TFT connecting portions lip) include holes OP to reduce an occurrence of short circuit between the common electrode 11h and the pixel electrodes 11g. The insulating films 16, 19, 20, 22, and 25 are formed in solid patterns to cover about the entire display area AA of the array board 11b except for the contact holes CH1 and CH2.

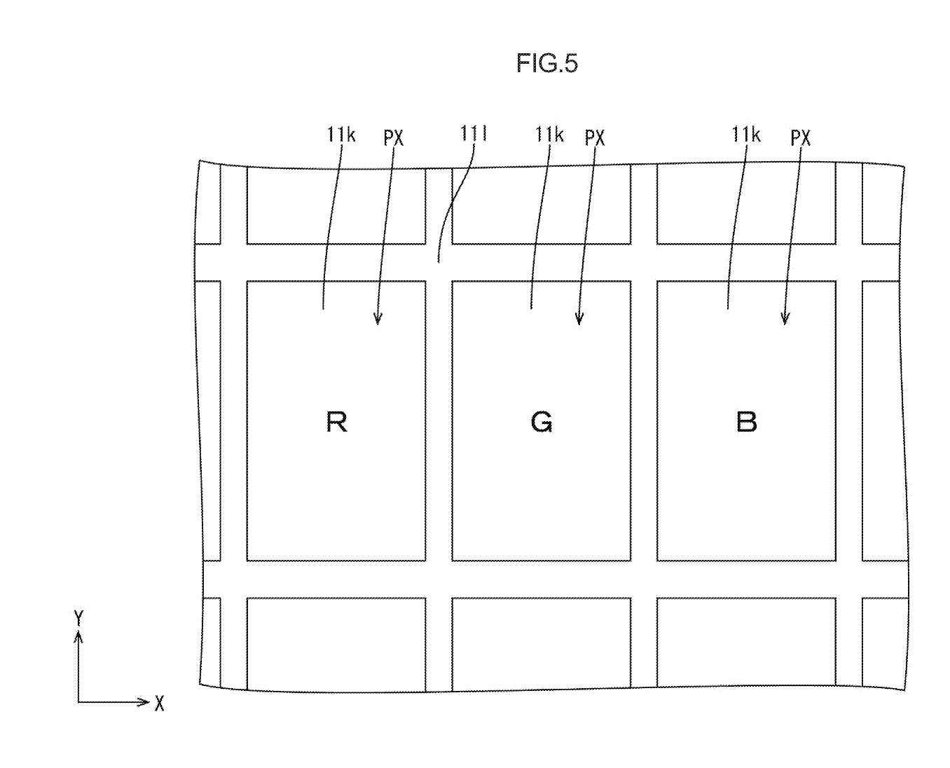

As illustrated in FIGS. 3 and 5, on the inner surface of the CF board 11a in the display area AA, color filters 11k are arranged at positions opposed to the pixel electrodes 11g on the array board 11b. The color filters 11k include red (R), green (G), and blue (B) color portions in three colors. The R color portions, the G color portions, and the B color portion are repeatedly arranged to form a matrix. The color portions (the pixels PX) of the color filters 11k arranged in the matrix are separated from one another with a light blocking portion 111 (a black matrix). With the light blocking portion ill, color mixture of different colors of light rays that pass through the color portions is less likely to occur. The light blocking portion 111 is formed in a grid in the plan view. The light blocking portion 111 includes dividing sections and a frame section. The dividing sections form a grid shape in the plan view and separate the color portions from one another. The frame section has a frame shape (a picture frame shape) in the plan view and surrounds the dividing sections from the peripheral sides. The dividing sections of the light blocking portion 111 are disposed to overlap the gate lines 11i and the source lines 11j in the plan view. The frame section of the light blocking portion 111 extends along the sealing member and has a vertically-long rectangular shape in the plan view. An overcoat film 11m (a planarization film) is disposed over surfaces of the color filters 11k and the light blocking portion 111 on the inner side. In the liquid crystal panel 11, each color portion of the color filter 11k and the pixel electrode 11g that is opposed to the color portion form a single pixel PX. The pixels PX include red pixels, green pixels, and blue pixels. The red pixels include the R color portions of the color filters 11k. The green pixels include the G color portions of the color filters 11k. The blue pixels include the B color portions of the color filters 11k. The pixels PX in three colors are repeatedly arranged along the row direction (the X-axis direction) on the plate surface of the liquid crystal panel 11 to form pixel lines. A number of the pixel lines are arranged along the column direction (the Y-axis direction). Namely, a number of the pixels PX are arranged in a matrix in the display area AA of the liquid crystal panel 11. Alignment films 11n and 11o are formed in inner most layers on the boards 11a and 11b to contact the liquid crystal layer 11c. The alignment films 11n and 11o are for orientating the liquid crystal molecules in the liquid crystal layer 11c.

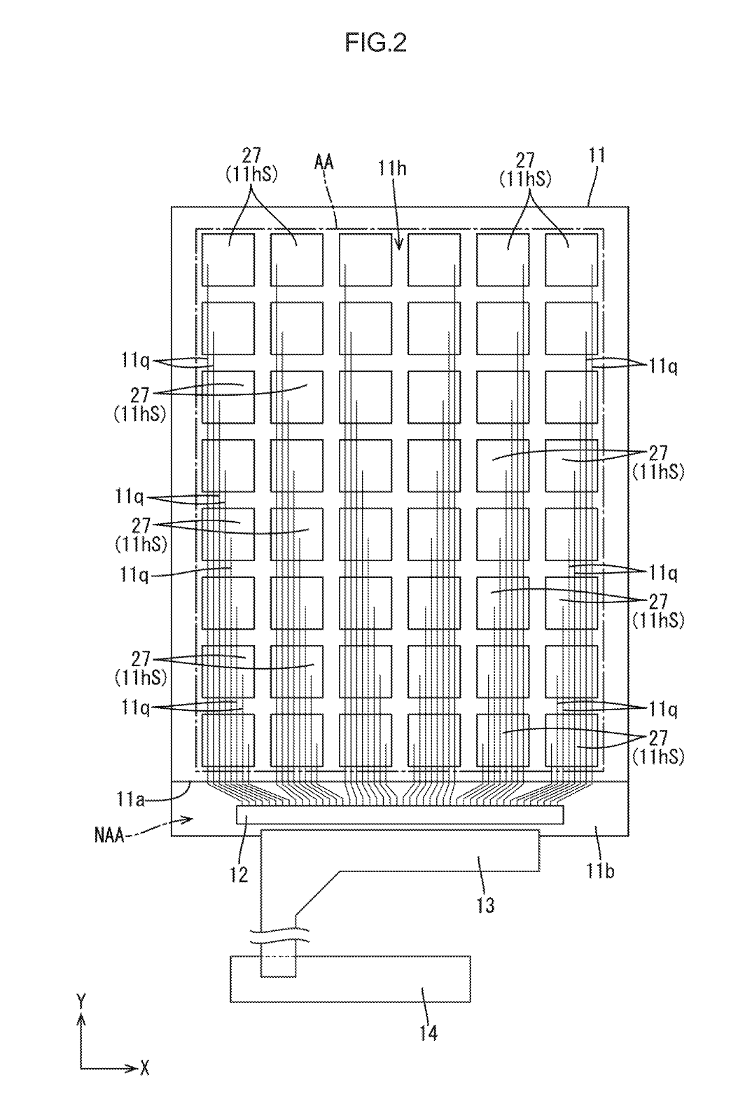

As described earlier, the liquid crystal panel 11 according to this embodiment has the display function and the position input function (the position detection function). The display function is for displaying images. The position input function is for detecting positions (input positions) input by the user based on images that are displayed. The liquid crystal panel 11 includes a touchscreen pattern integrated therein (in-cell touchscreen technology) for performing the position input function. The touchscreen pattern uses a so-called projection type electrostatic capacitance method. A detection method of the touchscreen pattern is a self-capacitance method. As illustrated in FIG. 2, the touchscreen pattern is formed on the array board 11b of the pair of boards 11a and 11b. The touchscreen pattern includes position detection electrodes 27 arranged in a matrix within a plane of the array board 11b. The position detection electrodes 27 are disposed in the display area AA of the array board 11b. The display area AA of the liquid crystal panel 11 substantially corresponds with a touching area in which input positions can be detected. The non-display area NAA of the liquid crystal panel 11 substantially corresponds with a non-touching area in which the input positions cannot be detected. When the user brings his or her finger (a position detection object), which is a conductive member, closer to the surface of the liquid crystal panel 11 to input a position based on the image displayed in the display area AA of the liquid crystal panel 11, an electrostatic capacitance is obtained between the finger and the position detection electrode 27. The electrostatic capacitance detected by the position detection electrode 27 closer to the finger varies from the electrostatic capacitance when the finger is away from the position detection electrode 27 as the finger approaches thereto. The electrostatic capacitance detected at the position detection electrode 27 closer to the finger is different from the electrostatic capacitance detected at any of the other position detection electrodes 27 away from the finger. Therefore, the input position can be detected based on the difference in electrostatic capacitance. A parasitic capacitance may exist between the position detection electrode 27 away from the finger and a conductive member other than the finger.

The position detection electrodes 27 are included in the common electrode 11h in the array board 11b. As illustrated in FIG. 2, the common electrode 11h includes common electrode segments 11hS that are separated from each other and arranged in a grid within the plane of the array board 11b. The common electrode segments 11hS are configure as the position detection electrodes 27. In comparison to a configuration in which position detection electrodes are provided separately from the common electrode 11h, the configuration of this embodiment is more preferable for simplifying the structure and reducing the cost. The position detection electrodes 27 (or the common electrode segments 11hS) are arranged in lines along the X-axis direction (the row direction) and in lines along the Y-axis direction (the column direction) to form a matrix. Each position detection electrode 27 has a rectangular shape in a plan view and sides, each of which is some millimeters. Namely, each position detection electrode 27 is larger than each pixel PX (the pixel electrode 11g) in the plan view and disposed in an area in which the multiple pixels PX are arranged along the X-axis direction and Y-axis direction. FIG. 2 schematically illustrates the arrangement of the position detection electrodes 27. The number and the arrangement of the position detection electrodes 27 may be altered from those in the drawing where appropriate.

As illustrated in FIG. 2, position detection lines 11q are connected to the position detection electrodes 27 (or the common electrode segments 11hS). In the display area AA, the position detection lines 11q linearly extend along the Y-axis direction, that is, the extending direction of the source lines 11j (the column line). The position detection lines 11q have lengths corresponding to the position detection electrodes 27 to which the position detection lines 11q are connected, respectively. Namely, a first end of each position detection line 11q is disposed over the corresponding position detection electrode 27 to which the first end is connected in the display area AA and a second end of each position detection line 11q disposed in the non-display area NAA is connected to the driver 12. The driver 12 is configured to drive the TFTs 11f for image display and the position detection electrodes 27 for position detection. Namely, the driver 12 has a display function and a position detection function. As described earlier, the position detection lines 11q are formed from the fourth metal film 23 and the position detection electrodes 27, that is, the common electrode 11h is formed from the first transparent electrode film 24. The position detection electrodes 11q are directly connected to the position detection electrodes 27 without contact holes. The position detection lines 11q are connected to not only the position detection electrodes 27 to which the respective position detection electrodes 27 are connected but also other position detection electrodes 27 between the position detection electrodes 27 and the driver 12. According to the configuration in which the position detection lines 11q are connected to the position detection electrodes 27 in each column (the position detection electrodes 27 arranged along the extending direction of the position detection lines 11q), the position detection electrode 27 to which the position is actually input can be identified by extracting a combination of the position detection lines 11q that have detected the position from the position detection lines 11q in the same column. As illustrated in FIG. 4, the position detection lines 11q are disposed to overlap the specific source lines 11j (the light blocking portion 111) in the plan view but not the pixels PX. According to the arrangement, a reduction in aperture ratio of the pixels PX by the position detection lines 11q is less likely to occur.

Next, the configuration of the section of the array board 11b in the non-display area NAA will be described. A non-overlapping section of the array board in the non-display area NAA does not overlap the CF board 11a. As illustrated in FIG. 1, the end of the flexible circuit board 13 and the driver 12 are mounted in the non-overlapping area. The end of the flexible circuit board 13 is disposed in an edge area of the non-overlapping section along the short direction of the array board 11b (the X-axis direction). The driver 12 is disposed on the array board 11b closer to the display area AA relative to the flexible circuit board 13. In the driver 12 mounting area of the array board 11b in which the driver 12 is mounted, output terminals (not illustrated) and the input terminals 28 (terminals) are disposed. The output terminals are for outputting signals to the driver 12. The input terminals 28 are for receiving signals from the driver 12. In the flexible circuit board 13 mounting area of the array board 11b in which the flexible circuit board 13 is mounted, flexible board connecting terminals (not illustrated) connected to the flexible circuit board 13 are disposed. The input terminals 28 are disposed closer to the display area AA in comparison to the other terminals (the output terminals and the flexible circuit board connected terminals) with respect to the Y-axis direction.

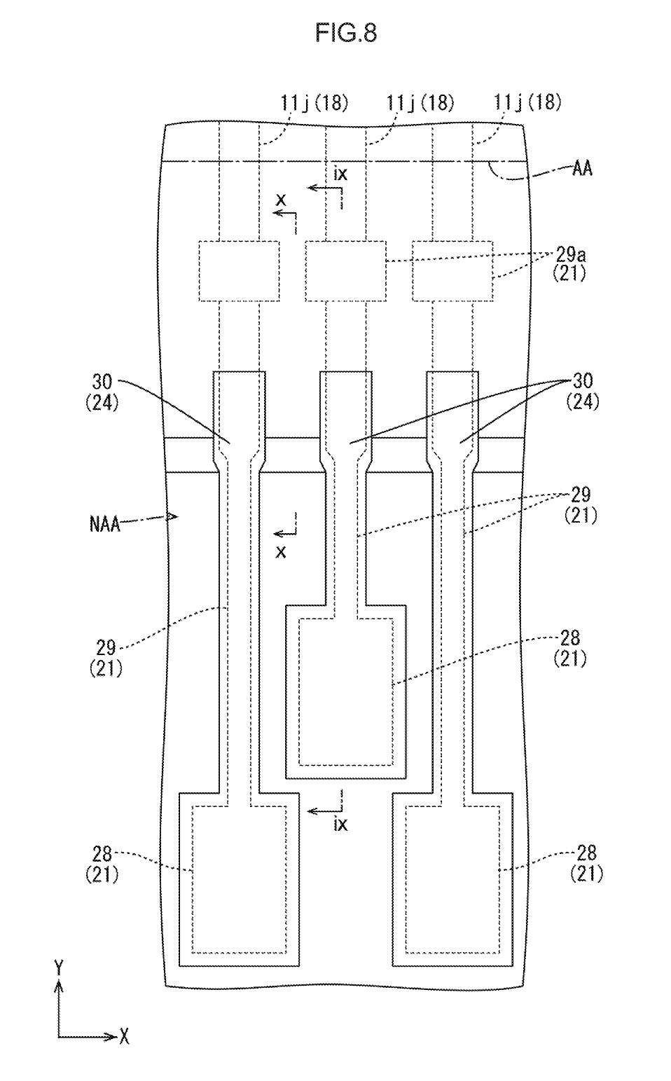

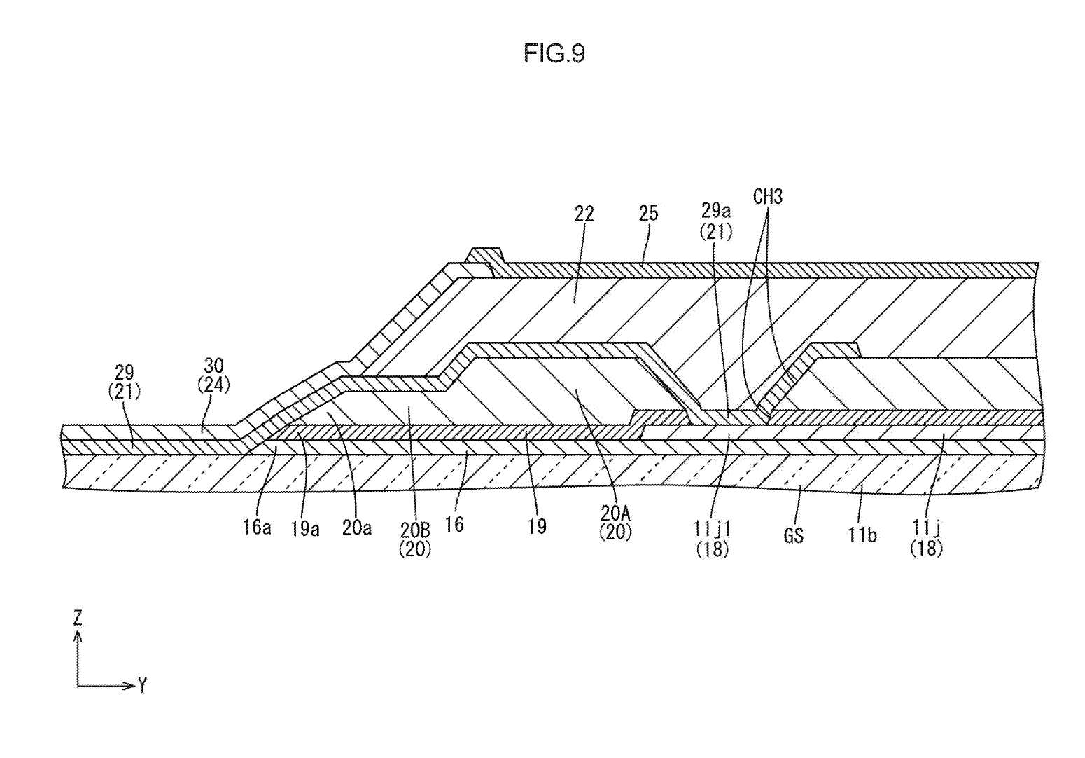

As illustrated in FIG. 8, the input terminals 28 are two-dimensionally arranged in a zigzag pattern in the driver 12 mounting area and connected to the terminal lines 29, which will be described next. The terminal lines 29 are disposed at predefined intervals along the X-axis direction in the section of the array board 11b in the non-display area NAA. The terminal lines 29 extend in the Y-axis direction. First ends of the terminal lines 29 are connected to the input terminals 28 and second ends of the terminal lines 29 (on the display area AA side) are connected to the ends of the source lines 11j, respectively. Large sections of the source lines 11j are disposed in the display area AA but some sections of the source lines 11j (including line overlapping sections 11j1) are disposed in the non-display area NAA. As illustrated in FIG. 9, the input terminals 28 and the terminal lines 29 are formed from the third metal film 21 that also forms the TFT connecting portions 11p. The terminal lines 29 are disposed in a layer upper than the source lines 11j to which the terminal lines 29 are connected via the first interlayer insulating film 19 and the first planarization film 20. The ends of the terminal lines 29 on an opposite side from the input terminals 28 and ends of the source lines 11j on an opposite side from the TFTs 11f are disposed to overlap each other in the plan view in the section of the array board 11b in the non-display area NAA. Overlapping sections of the source lines 11j and the terminal lines 29 are defined as line overlapping sections 11j1 and 29a. The first interlayer insulating film 19 and the first planarization film 20 disposed between the terminal lines 29 and the source lines 11j include line contact holes CH3 at positions overlapping the line overlapping sections 11j1 of the terminal lines 29 and the line overlapping sections 29a of the source lines 11j in the plan view. The line contact holes CH3 are for connecting the line overlapping sections 11j1 and 29a to each other. The signals output by the driver 12 are fed to the source electrodes 11f2 of the TFTs 11f via the input terminals 28, the terminal lines 29, and the source lines 11j.

As illustrated in FIGS. 8 and 9, sections of the insulating films 16, 19, 20, 22, and 25 closer to the driver 12 mounting area and the flexible circuit board 13 mounting area are removed in the section of the array board 11b in the non-display area NAA. Edge sections 16a, 19a, 20a, 22a, and 25a of the insulating films 16, 19, 20, 22, and 25 are disposed between the display area AA and the input terminals 28 closest to the display area AA among the terminals with respect to the Y-axis direction. Entire areas of the input terminals 28 are formed directly on the glass substrate GS of the array board 11b. The terminal lines 29 include sections that are formed directly on the glass substrate GS of the array board 11b. The rest of sections (sections on the source line 11j side) of the terminal lines 29 are formed in a layer upper than the first interlayer insulating film 19 and the first planarization film 20. Namely, the terminal lines 29 run on the first interlayer insulating film 19 and the first planarization film 20 on the way from the input terminal 28 side toward the source line 11j side. The terminal lines 29 are disposed across at least a first interlayer insulating film edge section 19a of the first interlayer insulating film 19 and a first planarization film edge section 20a of the first planarization film 20. The edge sections 16a, 19a, 20a, 22a, and 25a of the insulating films 16, 19, 20, 22, and 25 are angled relative to the plate surface of the glass substrate GS with acute angles larger than 0°. Furthermore, the edge sections 16a, 19a, 20a, 22a, and 25a disposed in the lower layers (closer to the glass substrate GS) with respect to the Z-axis direction are closer to the input terminals 28 with respect to the Y-axis direction.

As illustrated in FIGS. 8 and 9, the protective members 30 are disposed to cover sections of the terminal lines 29 on the input terminal 28 side not overlapping the insulating films 22 and 25 in the layers upper than the terminal lines 29. The protective members 30 are formed from the first transparent electrode film 24 that also forms the common electrode 11h. The protective members 30 cover not only the sections of the terminal lines 29 described above but also the input terminals 28. During wet-etching of the first transparent electrode film 24 performed after forming and exposure steps in production of the array board 11b, aluminum layers of sections of the terminal lines 29 and the input terminals 28 formed from the third metal film 21 having a three-layer structure are more likely to be etched with an etching solution in comparison to titanium layers. Therefore, the aluminum layers of the sections of the terminal lines 29 and the input terminals 28 may be narrower than the titanium layers. Namely, side-shift defects may be caused. Because the sections of the terminal lines 29 and the input terminals 28 are covered with the protective members 30 as described above, the sections of the terminal lines 29 and the input terminals 28 are protected with the protective members 30 from the etching solution during the wet-etching of the first transparent electrode film 24 that are formed and exposed. Therefore, the terminal lines 29 and the input terminals 28 are less likely to have the side-shift defects.

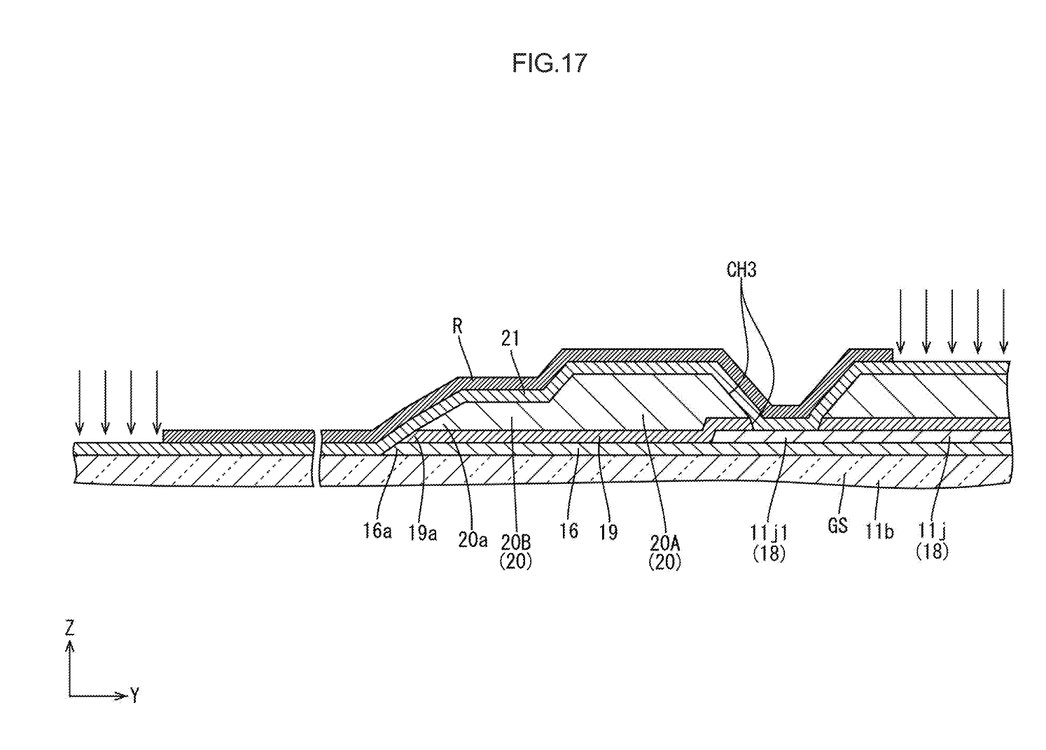

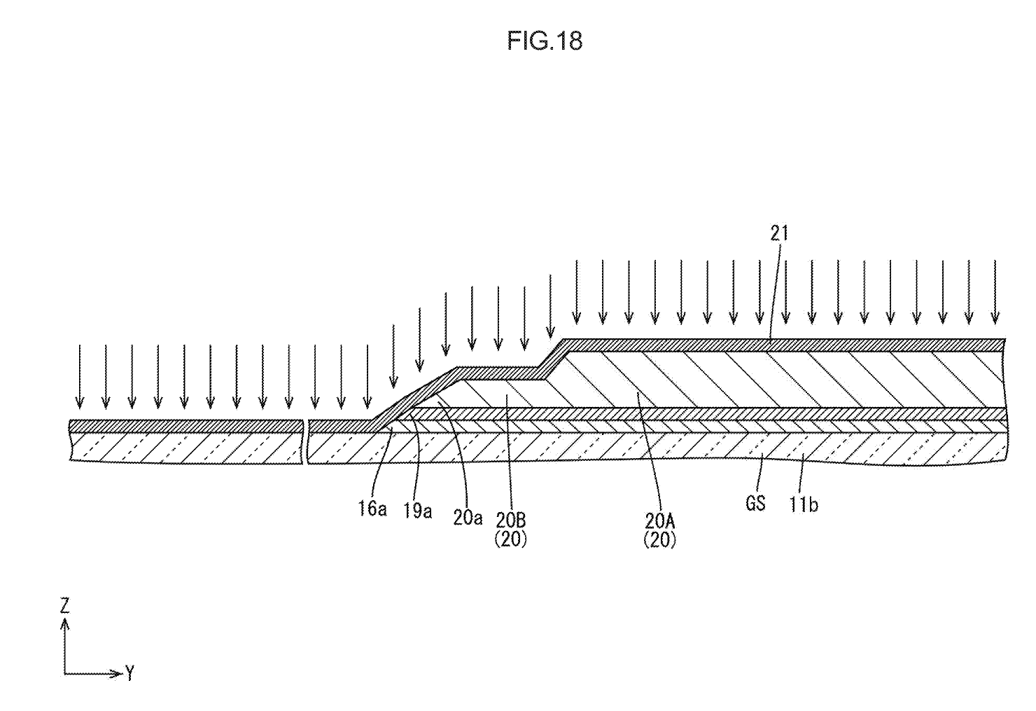

In the production of the array board 11b according to this embodiment, the gate insulating film 16 and the first interlayer insulating film 19 are patterned using the first planarization film 20 disposes in the layer upper than the gate insulating film 16 and the first interlayer insulating film 19 as a mask. Therefore, the angle of slope of the gate insulating film edge section 16a and the first interlayer insulating film edge section 19a relative to the plate surface of the glass substrate GS tends to be larger than the angle of slope of the first planarization film edge section 20a. In the production of the array board 11b, the terminal lines 29 are formed by etching the third metal film 21 disposed in the layer upper than the first planarization film 20 via the photoresist R (the resist) (see FIGS. 17 and 18). The section of the third metal film 21 disposed in the layer upper than the first planarization film 20 overlapping the gate insulating film edge section 16a and the first interlayer insulating film edge section 19a is less likely to be removed through the etching in comparison to the section overlapping the first planarization film edge section 20a due to a difference in angle of slope. If the section of the third metal film 21 overlapping the gate insulating film edge section 16a and the first interlayer insulating film edge section 19a remains without being removed, a short circuit may occur between the adjacent terminal lines 29.

In the configuration in which the terminal lines 29 are partially disposed on the gate insulating film 16, the first interlayer insulating film 19, and the first planarization film 20, uneven exposure may occur during the exposure of the third metal film 21 that forms the terminal lines 29 after the formation of the third metal film 21 in the production of the array board 11b. In the step of exposing the third metal film 21, the exposure is performed with a focus on the sections of the terminal lines 29 not overlapping the gate insulating film 16, the first interlayer insulating film 19, and the first planarization film 20 (the sections directly formed on the glass substrate GS). Therefore, the sections of the terminal lines 29 overlapping the gate insulating film 16, the first interlayer insulating film 19, and the first planarization film 20 (the sections on the gate insulating film 16, the first interlayer insulating film 19, and the first planarization film 20) are out of focus. As a result, the uneven exposure occurs. As illustrated in FIG. 9, the sections of the terminal lines 29 overlapping the gate insulating film 16, the first interlayer insulating film 19, and the first planarization film 20 tend to be wider than the sections of the terminal lines 29 not overlapping the gate insulating film 16, the first interlayer insulating film 19, and the first planarization film 20. A distance between the sections of the adjacent terminal lines 29 overlapping the gate insulating film 16, the first interlayer insulating film 19, and the first planarization film 20 is smaller than a distance between the sections of the adjacent terminal lines 29 not overlapping the gate insulating film 16, the first interlayer insulating film 19, and the first planarization film 20. If residues of the third metal film 21 are produced in the sections overlapping the gate insulating film edge section 16a and the first interlayer insulating film edge section 19a, the adjacent terminal lines 29 are more likely to be shorted.

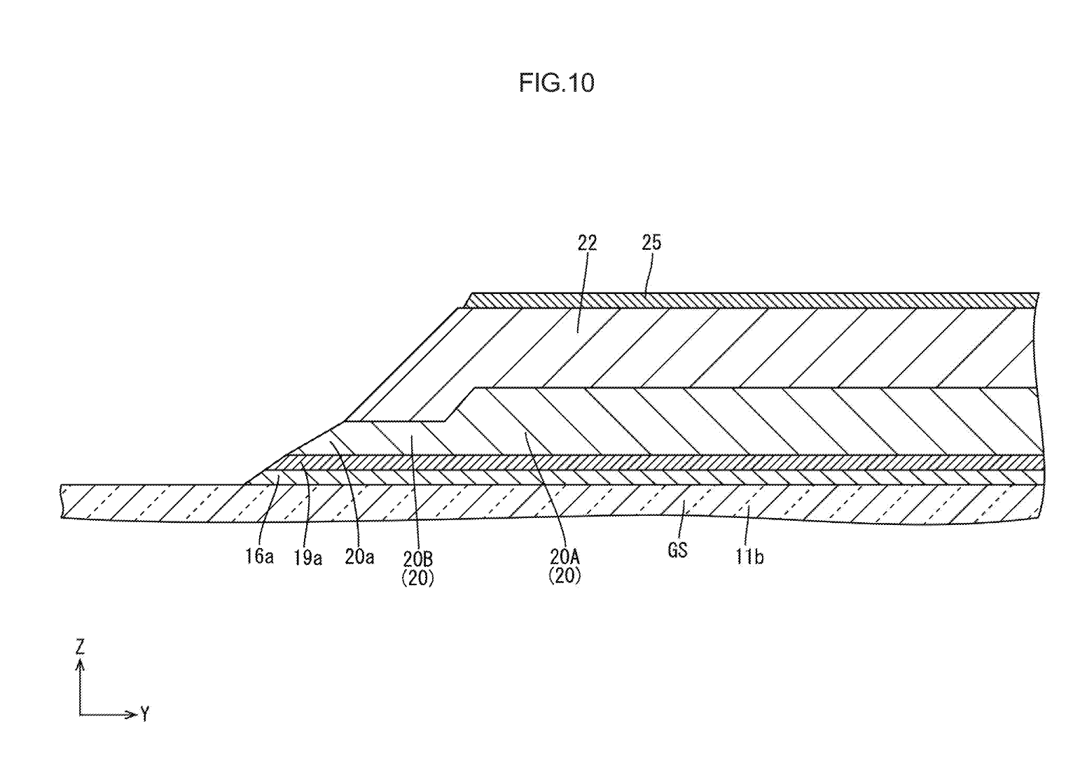

Therefore, as illustrated in FIGS. 9 and 10, the gate insulating film edge section 16a of the gate insulating film 16 and the first interlayer insulating film edge section 19a of the first interlayer insulating film 19 are angled relative to the plate surface of the glass substrate GS with the angles larger than 0° and smaller than 35°. According to the configuration, when forming the terminal lines through patterning, the sections of the third metal film 21 disposed in the layer upper than the first planarization film 20 overlapping the gate insulating film edge section 16a and the first interlayer insulating film edge section 19a are less likely to be removed through etching. Therefore, the residues of the third metal film 21 are less likely to be produced in the sections between the adjacent terminal lines 29 overlapping the gate insulating film edge section 16a and the first interlayer insulating film edge section 19a. Therefore, the adjacent terminal lines 29 are less likely to be shorted. Furthermore, the gate insulating film edge section 16a of the gate insulating film 16 and the first interlayer insulating film edge section 19a of the first interlayer insulating film 19 are angled relative to the plate surface of the glass substrate GS with the angles larger than 0° and smaller than 35° for the entire areas. When the terminal lines 29 are formed through patterning, the entire sections of the third metal film 21 disposed in the layer upper than the first planarization film 20 overlapping the gate insulating film edge section 16a and the first interlayer insulating film edge section 19a are more likely to be removed through etching. Therefore, the residues of the third metal film 21 are less likely to be produced in the sections between the adjacent terminal lines 29 overlapping the entire areas of the gate insulating film edge section 16a and the first interlayer insulating film edge section 19a. In comparison to a configuration in which only parts of the gate insulating film edge section 16a and the first interlayer insulating film edge section 19a are angled relative to the plate surface of the glass substrate GS with the angles larger than 0° and smaller than 35°, the reliability in short circuit protection can be further improved. The angle of the gate insulating film edge section 16a and the angle of the first interlayer insulating film edge section 19a relative to the plate surface of the glass substrate GS are about equal to each other.

As illustrated in FIGS. 9 and 10, the first planarization film 20 has two different thicknesses. The first planarization film 20 includes a first thickness portion 20A having a larger thickness and a second thickness portion 20B having a smaller thickness. The second thickness portion 20B is disposed closer to the input terminals 28 relative to the first thickness portion 20A with respect to the Y-axis direction. The second thickness portion 20B includes the first planarization film edge section 20a. Because the thickness of the second thickness portion 20B is smaller than the thickness of the first thickness portion 20A, in comparison to the configuration in which the thickness of the first planarization film 20 is equal to the thickness of the first thickness portion 20A for the entire area, an angle of slope of the first planarization film edge section 20a included in the second thickness portion 20B relative to the plate surface of the glass substrate GS is smaller. When the gate insulating film 16 and the first interlayer insulating film 19 are patterned with the first planarization film 20 as a mask in the production of the array board 11b, the angles of the gate insulating film edge section 16a and the first interlayer insulating film edge section 19a relative to the plate surface of the glass substrate GS can be further reduced. The angles of slopes of the gate insulating film edge section 16a and the first interlayer insulating film edge section 19a can be easily maintained larger than 0° and smaller than 35°. Therefore, the reliability in short circuit protection between the adjacent terminal lines 29 is further improved.

Comparative experiment 1 was conducted to observe how the residues of the third metal film 21 in the sections overlapping the gate insulating film edge section 16a and the first interlayer insulating film edge section 19a varied as the angles of the gate insulating film edge section 16a of the gate insulating film 16 and the first interlayer insulating film edge section 19a of the first interlayer insulating film 19 relative to the plate surface of the glass substrate GS were varied. In comparative experiment 1, comparative example 1 in which the angle of slope of the gate insulating film edge section 16a and the first interlayer insulating film edge section 19a was set to 54°, comparative example 2 in which the angle of slope of the gate insulating film edge section 16a and the first interlayer insulating film edge section 19a was set to 40°, embodiment 1 in which the angle of slope of the gate insulating film edge section 16a and the first interlayer insulating film edge section 19a was set to 35°, embodiment 2 in which the angle of slope of the gate insulating film edge section 16a and the first interlayer insulating film edge section 19a was set to 13°, embodiment 3 in which the angle of slope of the gate insulating film edge section 16a and the first interlayer insulating film edge section 19a was set to 5°, and embodiment 4 in which the angle of slope of the gate insulating film edge section 16a and the first interlayer insulating film edge section 19a was set to 2° were used. In comparative experiment 1, whether or not the residues of the third metal film 21 were present in the sections between overlapping the gate insulating film edge section 16a and the first interlayer insulating film edge section 19a were observed after the third metal film 21 was formed on the array board 11b in each comparative example and embodiment and patterned. The results are provided in a table in FIG. 11. In each of comparative examples 1 and 2, the residues of the third metal film 21 were observed. In each of embodiments 1 through 5, the residues of the third metal film 21 were not observed. The results suggest that the residues of the third metal film 21 may be produced in the sections overlapping the gate insulating film edge section 16a and the first interlayer insulating film edge section 19a when the angle of slope of the gate insulating film edge section 16a and the first interlayer insulating film edge section 19a relative to the plate surface of the glass substrate GS is larger than 35°, which may result in a short circuit between the adjacent terminal lines 29. When the angle of slope is equal to or smaller than 35° (excluding 0°, 0°<θ≤35° where θ is the angle of slope, especially, 0°<θ≤2°), the residues of the third metal film 21 are less likely to be produced in the sections overlapping the gate insulating film edge section 16a and the first interlayer insulating film edge section 19a. Therefore, sufficiently high reliability can be achieved in short circuit protection between the adjacent terminal lines 29.

The liquid crystal panel 11 according to this embodiment has the configuration described above. Next, a method of producing the liquid crystal panel 11 and operation thereof will be described. The liquid crystal panel 11 according to this embodiment is produced by bonding the CF board 11a and the array board 11b that are separately produced. A method of producing the array board 11b included in the liquid crystal panel 11 will be described in detail.

The method of producing the array board 11b includes at least a first metal film forming process, a gate insulating film forming process (a lower layer-side first insulating film forming process, a first insulating film forming process), a semiconductor film forming process, a second metal film forming process, a first interlayer insulating process (an upper layer-side first insulating film forming process, a first insulating film forming process), a first planarization film forming process (a second interlayer insulating film forming process), a first planarization film shaping process (a second insulating film shaping process), a gate insulating film and first interlayer insulating film shaping process (a first insulating film shaping process), a third metal film forming process (a metal film forming process), and a terminal line forming process. The first metal film forming process includes forming the first metal film 15 and forming the gate lines 11i and the gate electrodes 11f1. The gate insulating film forming process includes forming the gate insulating film 16. The semiconductor film 17 includes forming the semiconductor film 17 and forming the channels 11f4. The second metal film forming process includes forming the second metal film 18 and forming the source lines 11j, the source electrodes 11f2, and the drain electrodes 11f3. The first interlayer insulating film forming process includes forming the first interlayer insulating film 19. The first planarization film forming process includes the first planarization film 20. The first planarization film shaping process includes patterning the first planarization film 20 to form the first planarization film edge section 20a. The gate insulating film and first interlayer insulating film forming process includes patterning the gate insulating film 16 and the first interlayer insulating film 19 with the first planarization film 20 as a mask. The third metal film forming process includes forming the third metal film 21. The terminal line forming process includes patterning the third metal film 21 to form at least terminal lines 29. Processes related to the films 22 to 26 in the layers upper than the third metal film 21 in this embodiment will not be described.

In the gate insulating film forming process included in the method of producing the array board 11b, the gate insulating film 16 is formed in the layer upper than the plate surface of the glass substrate GS and the first metal film 15. In the first interlayer insulating film forming process, the first interlayer insulating film 19 is formed in the layer upper than the gate insulating film 16, the semiconductor film 17, and the second metal film 18 that are formed on the glass substrate GS in advance. The first interlayer insulating film 19 is formed in the solid pattern over an about entire area of the display area AA and the non-display area NAA of the array board 11b. In the first planarization film forming process, the first planarization film 20 is formed in the layer upper than the first interlayer insulating film 19. The first planarization film 20 is made of the positive-type photosensitive material. The first planarization film 20 is formed in the solid pattern over an about entire area of the display area AA and the non-display area NAA of the array board 11b similar to the first interlayer insulating film 19.

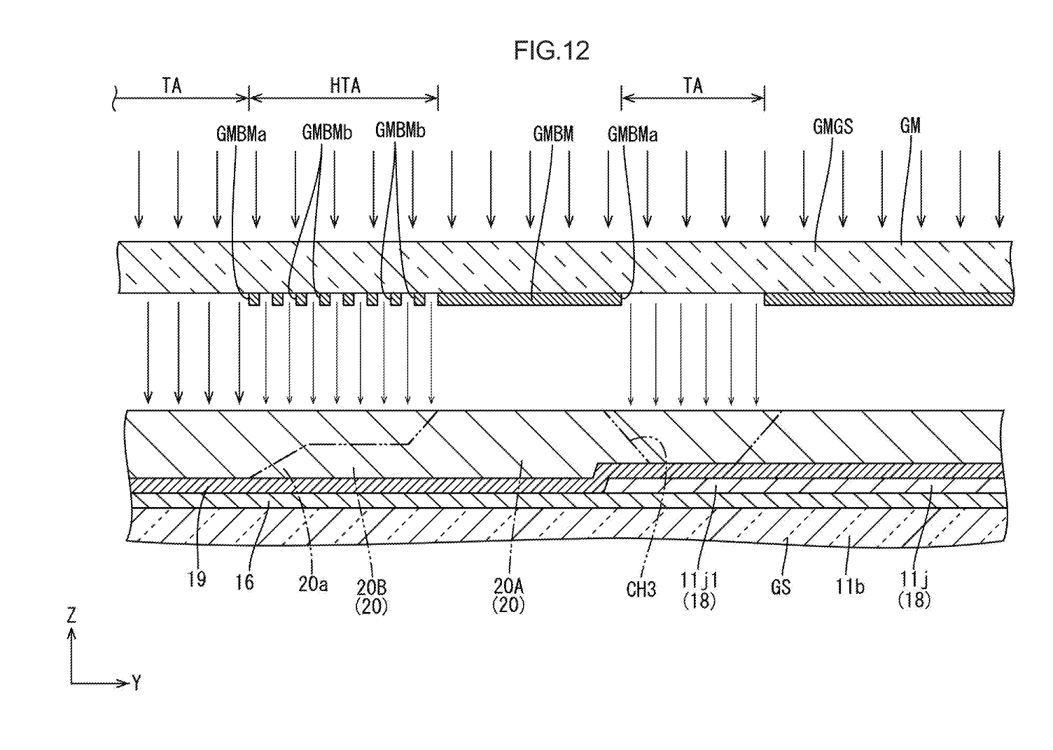

The first planarization film shaping process performed next includes an exposing step and a developing step. The exposing step includes exposing the first planarization film 20 made of the positive-type photosensitive material via a grey tone mask GM as a photomask. The developing step includes developing the first planarization film 20 that has been exposed. As illustrated in FIG. 12, the grey tone mask GM used in the exposing step includes a transparent glass base GMGS and a light blocking film GMBM formed on a plate surface of the glass base GMGS for blocking exposing light from the light source. The light blocking film GMBM includes holes GMBMa and slits GMBMb. The holes GMBMa are larger than resolution of the exposing device and the slits GMBMb are smaller than the resolution of the exposing device. The light blocking film GMBM is formed at a position overlapping a section of the first planarization film 20 in the solid pattern in which the first thickness portion 20A to be formed. The holes GMBMa are formed at positions not overlapping sections of the first planarization film 20 in the solid pattern which are not included in the first planarization film 20 after patterned (sections closer to the input terminals 28 relative to the first planarization film edge section 20a and sections in which the line contact holes CH3 to be formed. Similar holes are formed at positions overlapping sections in which the second TFT contact holes CH2, which are not illustrated, (see FIGS. 6 and 7) to be formed. The holes GMBMa may be referred to as transmissive areas TA having transmissivity of 100% to pass the exposing light. The slits GMBMb are formed at positions overlapping a section of the first planarization film 20 in the solid pattern in which the second thickness portion 20B to be formed. Namely, the slits GMBMb are formed in the section adjacent to the holes GMBMa on a display area AA side with respect to the Y-axis direction. The slits GMBMb are arranged at intervals. The slits GMBMb are referred to as a semitransmissive area HTA having transmissivity of 10% to 70% to pass the exposing light.

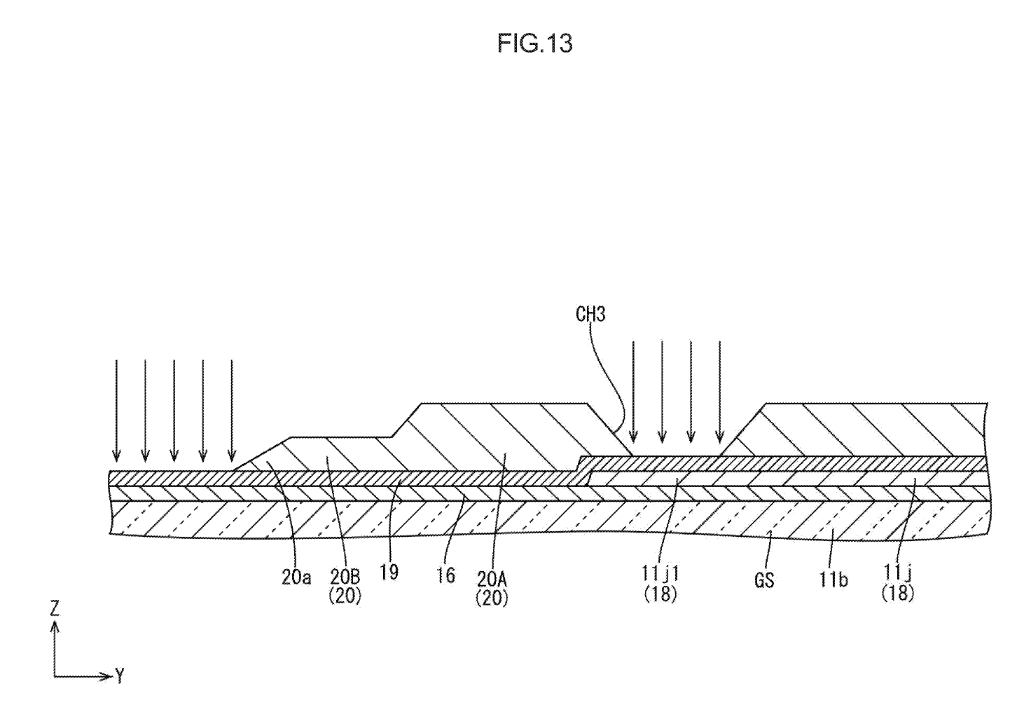

In the exposing step performed using the grey tone mask GM having such a configuration, when an ultraviolet ray, which is the exposing light from the light source, is applied to the first planarization film 20 in the solid pattern via the grey tone mask GM, an amount of applied light is larger in the section of the first planarization film 20 overlapping the holes GMBMa (the transmissive areas TA) and smaller in the section of the first planarization film 20 overlapping the slits GMBMb (the semitransmissive area HTA). When the developing step is performed afterward, as illustrated in FIG. 13, the thickness of the second thickness portion 20B of the first planarization film 20 is smaller and the thickness of the first thickness portion 20A of the first planarization film 20 is larger. Through a single exposing step, the first planarization film 20 that includes the sections having different thicknesses is formed. Therefore, time required for the production can be reduced. The first planarization film 20 that is patterned through the developing step includes the first planarization film edge section 20a that is angled relative to the plate surface of the glass substrate GS. The first planarization film edge section 20a is a part of the second thickness portion 20B having the smaller thickness. In comparison to a configuration in which the first planarization film 20 has a thickness that is equal to the thickness of the first thickness portion 20A for an entire area, the angle of slope relative to the plate surface of the glass substrate GS is smaller.

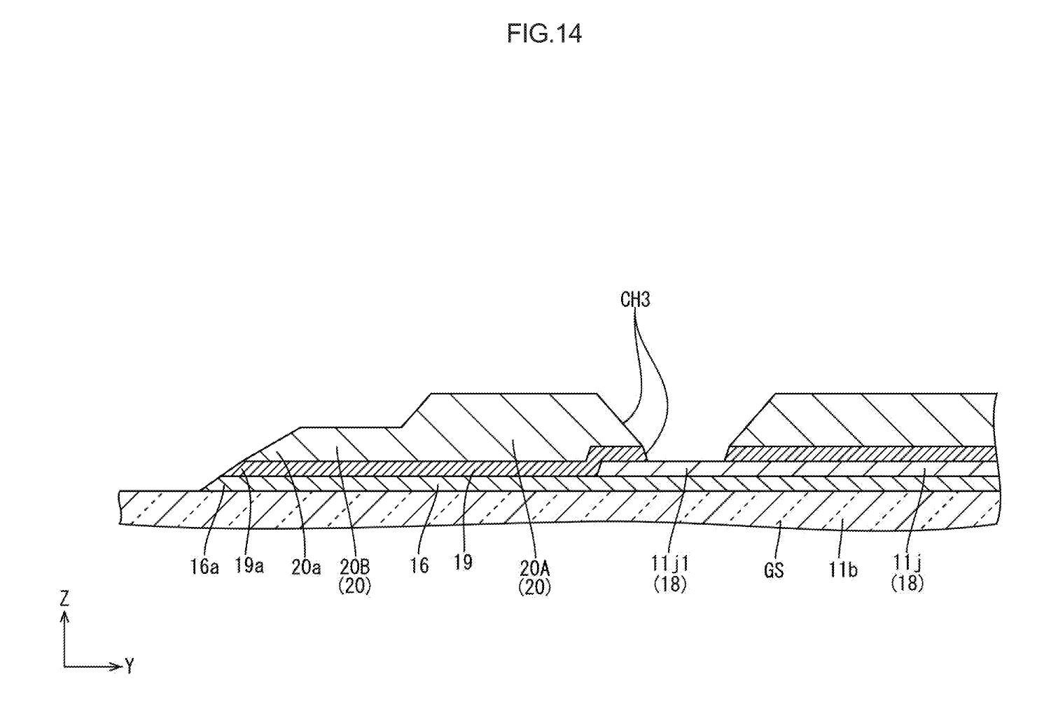

As illustrated in FIG. 13, in the gate insulating film and first interlayer insulating film forming process, the gate insulating film 16 and the first interlayer insulating film 19 in the solid patterns are etched with the first planarization film 20 are a mask. Sections of the gate insulating film 16 and the first interlayer insulating film 19 overlapping the first planarization film 20 (sections covered with the first planarization film 20) remain without being etched. As illustrated in FIG. 14, sections of the gate insulating film 16 and the first interlayer insulating film 19 not overlapping the first planarization film 20 (sections not covered with the first planarization film 20) are removed through etching. Namely, a two-dimensional shape of the first planarization film 20 is transferred onto the gate insulating film 16 and the first interlayer insulating film 19 that etched. The gate insulating film 16 and the first interlayer insulating film 19 that are patterned in the gate insulating film and first interlayer insulating film forming process include the gate insulating film edge section 16a and the first interlayer insulating film edge section 19a, respectively. The gate insulating film edge section 16a and the first interlayer insulating film edge section 19a are angled relative to the plate surface of the glass substrate GS. The gate insulating film edge section 16a and the first interlayer insulating film edge section 19a overlap the first planarization film edge section 20a of the second thickness portion 20B of the first planarization film 20 having the smaller thickness. In comparison to the configuration in which the first planarization film 20 has the thickness that is equal to the thickness of the first thickness portion 20A for the entire area, the angle of slope relative to the plate surface of the glass substrate GS is smaller. Therefore, the angle of slope of the gate insulating film edge section 16a and the first interlayer insulating film edge section 19a relative to the plate surface of the glass substrate GS is larger than the angle of slope of the first planarization film edge section 20a but can be maintained equal to or smaller than 35°.

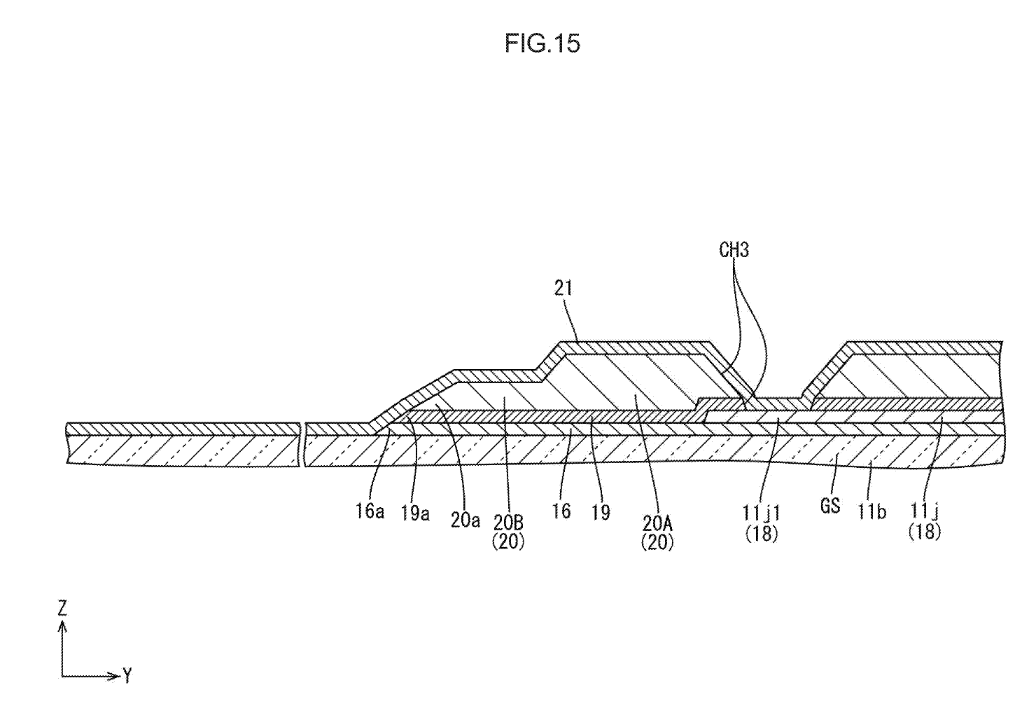

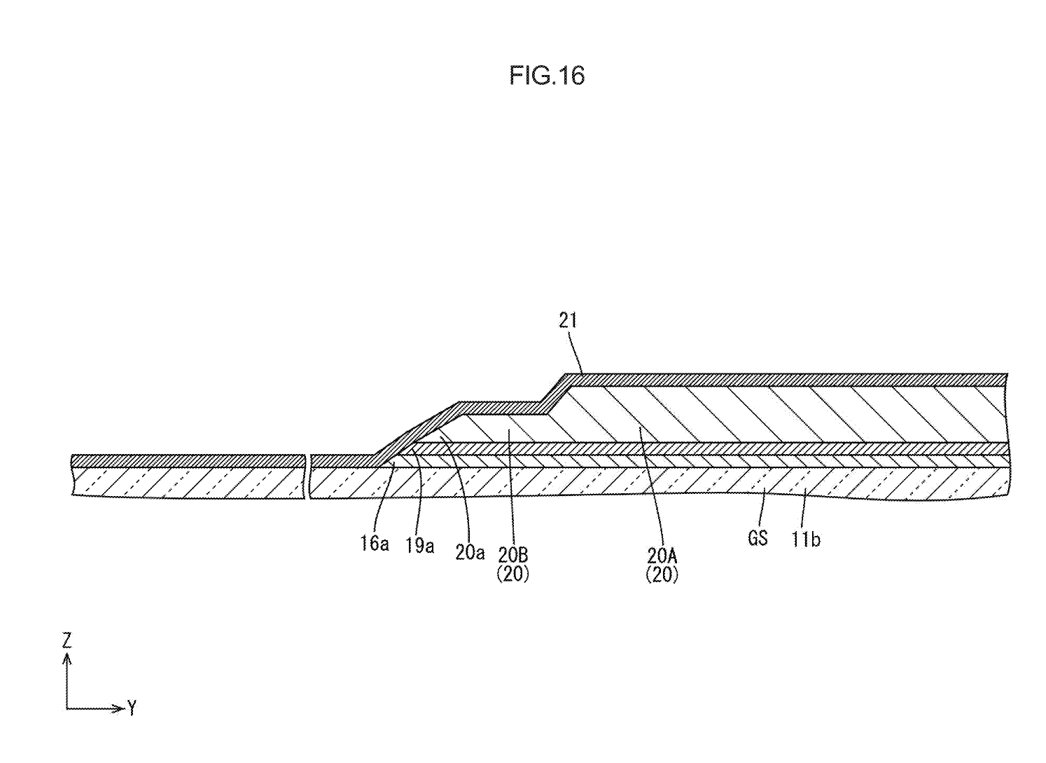

As illustrated in FIGS. 15 and 16, in the third metal film forming process, the third metal film 21 is formed in the layer upper than the first planarization film 20. The third metal film 21 is formed in a solid pattern over entire areas of the display area AA and the non-display area NAA of the array board 11b. The terminal line forming process performed afterward includes at least a resist forming process, an etching process, and a resist removal process. The resist forming process includes forming a photoresist R in a layer upper than the third metal film 21 in the solid pattern through patterning. The etching process includes etching the third metal film 21 via the photoresist R. The resist removal process includes removing the photoresist R. In the resist forming process, the photoresist R is applied to the upper side of the third metal film 21 in the solid pattern, exposed via a predefined photomask, and developed after the exposure. The photoresist R is patterned as illustrated in FIGS. 17 and 18. A forming area of the photoresist R that remains on the third metal film 21 after the patterning corresponds with the forming area of the terminal lines 29.

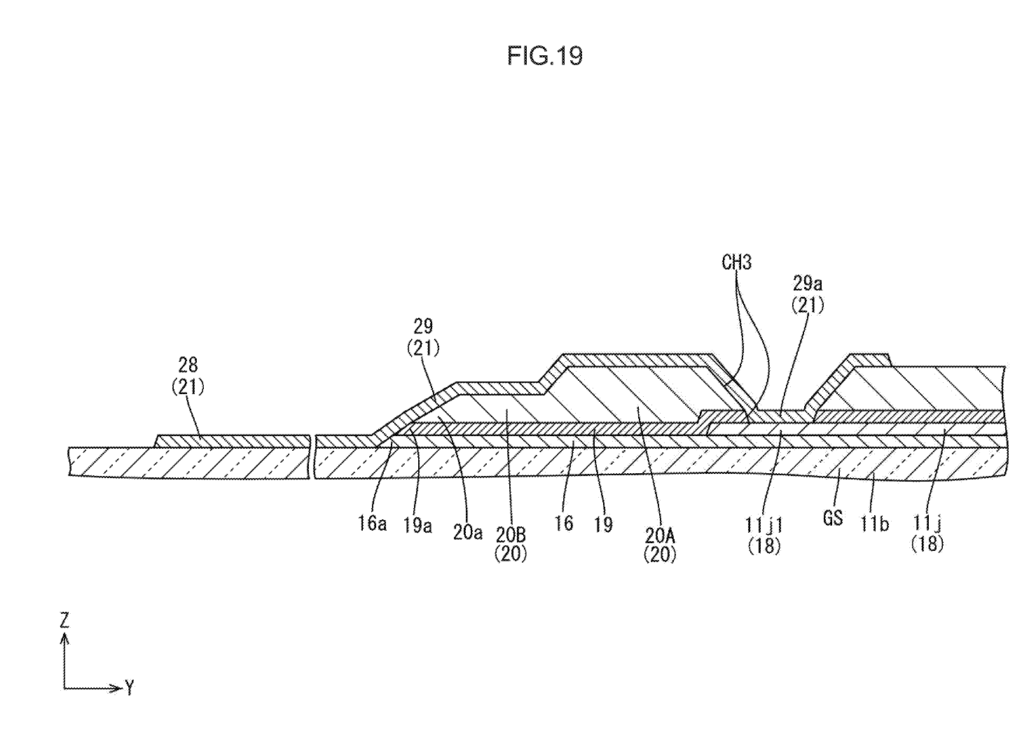

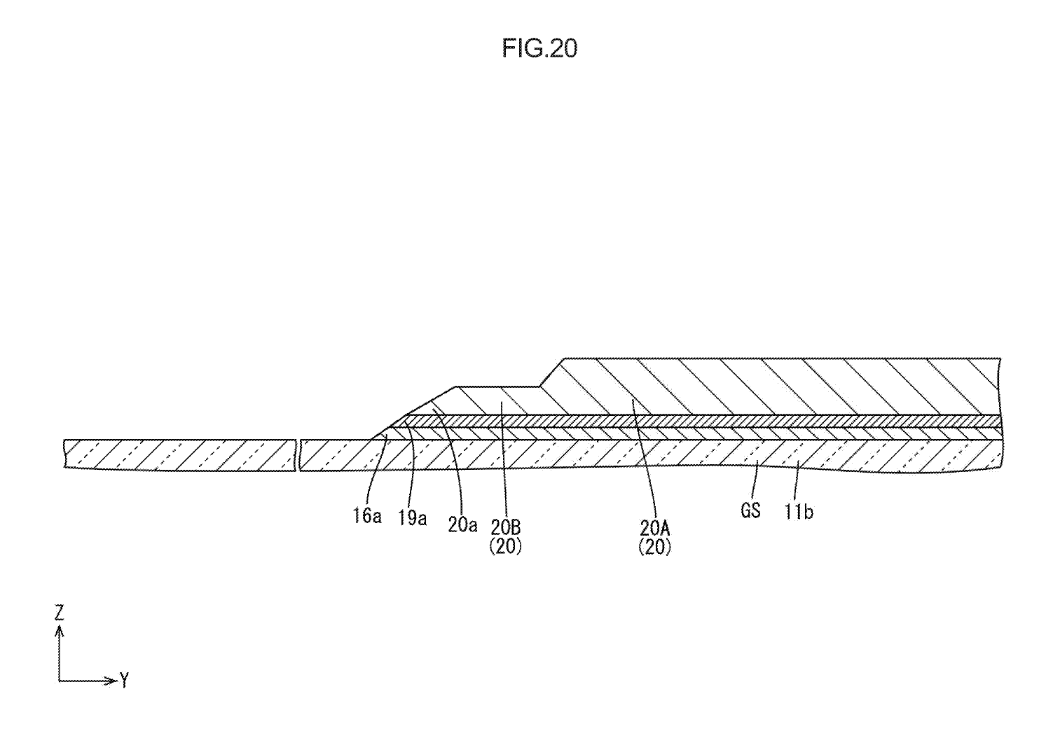

In the etching process, the third metal film 21 in the solid pattern is etched using the photoresist R as a mask. After the etching process, the photoresist R is removed in the resist removal process. Sections of the third metal film 21 in the solid pattern overlapping the photoresist R (sections covered with the photoresist R) remain without etched. As illustrated in FIG. 19, sections of the third metal film 21 in the solid pattern not overlapping the photoresist R (sections not covered with the photoresist R) are removed through the etching. Namely, the two-dimensional shape of the photoresist R is transferred onto the third metal film 21 that is etched and at least the terminal lines 29 are formed. In the etching process, it is preferable to use dry etching. As illustrated in FIG. 18, sections of the third metal film 21 in the solid pattern between the adjacent terminal lines 29 are not covered with the photoresist R and thus removed through the etching in the etching process. Among the sections of the third metal film 21 between the adjacent terminal lines 29, the sections overlapping the gate insulating film edge section 16a and the first interlayer insulating film edge section 19a may remain without removed through the etching because the gate insulating film edge section 16a and the first interlayer insulating film edge section 19a are angled relative to the plate surface of the glass substrate GS. Because the angle of slope of the gate insulating film edge section 16a and the first interlayer insulating film edge section 19a relative to the plate surface of the glass substrate GS is larger than 0° and equal to or smaller than 35°, as illustrated in FIG. 20, the sections of the third metal film 21 between the adjacent terminal lines 29 overlapping the gate insulating film edge section 16a and the first interlayer insulating film edge section 19a are properly removed through the etching. Therefore, residues of the third metal film 21 are less likely to remain without being removed between the adjacent terminal lines 29 and thus higher reliability can be achieved in the short circuit protection between the adjacent terminal lines 29. In the terminal line forming process, the TFT connecting portions 11p (see FIGS. 6 and 7) are formed simultaneously with the terminal lines 29.

Next, functions and operation of the liquid crystal panel will be described. The liquid crystal display device 10 according to this embodiment has the position input function. Therefore, the user of the liquid crystal display device 10 can input a position based on an image displayed in the display area AA of the liquid crystal panel 11. The common electrode 11h included in the array board 11b of the liquid crystal panel 11 is also the position detection electrodes 27. A common voltage (a reference voltage) which is a reference to voltages at the pixel electrodes 11g is applied to the common electrode 11h by the driver 12 for image display. A voltage for obtaining an electrostatic capacitance between the common electrode 11h and the finger is applied by the driver 12 for position detection. Namely, the driver 12 controls the driving of the liquid crystal panel 11 differently in a display period and a position detection period per unit period.

In the display period, the driver 12 supplies scan signals to the gate lines 11i, data signals (image signals) to the source lines 11j, and common voltage signals to the position detection lines 11q. As illustrated in FIGS. 4 and 8, the data signals output by the driver 12 are transmitted to the source lines 11j via the input terminals 28 and the terminal lines 29. When the TFTs 11f in a row selected based on the scan signals supplied to the gate lines 11i are turned on, voltages corresponding to the data signals supplied to the source lines 11j are applied to the pixel electrodes 11g via the channels 11f4 of the TFTs 11f. The common voltage is simultaneously applied to the common electrode segments 11hS of the common electrode 11h according to the common voltage signals supplied to the position detection lines 11q. Based on differences in voltage between the pixel electrodes 11g and the common electrode 11h, the pixels PX exhibit specified tones and thus a specified image is displayed in the display area AA of the liquid crystal panel 11.

In the position detection period, the driver 12 supplies position detection driving signals to the position detection lines 11q. If position input in the display area AA of the liquid crystal panel 11 is performed by the user of the liquid crystal display device 10 with his or her finger, an electrostatic capacitance is obtained between the finger and the position detection electrode 27 close to the finger. Namely, the electrostatic capacitance at the position detection electrode 27 closer to the finger is larger than the electrostatic capacitance at the position detection electrode 27 farther from the finger because the position detection electrode 27 closer to the finger and the finger have the electrostatic capacitance therebetween. When the electrostatic capacitances at the position detection electrodes 27 are detected by the driver 12 via the position detection lines 11q, the driver 12 extracts the capacitance that has varied from the detected electrostatic capacitances. The driver 12 obtains position information regarding the input position based on the position detection line 11q that has transmitted the electrostatic capacitance that has varied. As a result, the position input by the user with his or her finger can be detected.

As described above, the array board 11b (the display board) in this embodiment includes the glass substrate GS (the substrate), the input terminals 28 (the terminals), the gate insulating film 16, the first interlayer insulating film 19, the first planarization film 20, and the terminal lines 29. The glass substrate GS includes the display area AA in which images are displayed and the non-display area NAA disposed outside the display area to surround the display area AA. The input terminals 28 are disposed in the non-display area NAA. The gate insulating film 16 and the first interlayer insulating film 19 are disposed to cross the boundary between the display area AA and the non-display area NAA. The gate insulating film 16 and the first interlayer insulating film 19 include the edge section disposed between the input terminals 28 and the display area AA. The edge sections are the gate insulating film edge section 16a and the first interlayer insulating film edge section 19a (the first insulating film edge section). The gate insulating film edge section 16a and the first interlayer insulating film edge section 19a are angled relative to the plate surface of the glass substrate GS. The angle of slope of at least parts of the gate insulating film edge section 16a and the first interlayer insulating film edge section 19a is equal to or smaller than 35°. The first planarization film 20 is disposed in the layer upper than the gate insulating film 16 and the first interlayer insulating film 19 to cross the boundary between the display area AA and the non-display area NAA. The first planarization film 20 includes the edge section disposed between the input terminals 28 and the display area AA. The edge section is the first planarization film edge section 20a that is angled relative to the plate surface of the glass substrate GS. The angle of slope of the first planarization film edge section 20a is larger than the angle of slope of the gate insulating film edge section 16a and the first interlayer insulating film edge section 19a. The terminal lines 29 are formed from the third metal film 21 that is disposed in the layer upper than the first planarization film 20 at least in the non-display area NAA. The terminals lines are disposed to cross the gate insulating film edge section 16a, the first interlayer insulating film edge section 19a, and the first planarization film edge section 20a and connected to the input terminals 28.

The terminal lines 29 connected to the input terminals that are disposed in the non-display area NAA are disposed in the layer upper than the first planarization film 20 to cross the gate insulating film edge section 16a, the first interlayer insulating film edge section 19a, and the first planarization film edge section 20a that are disposed between the input terminals 28 and the display area AA. The first planarization film edge section 20a of the first planarization film 20 has the angle of slope relative to the plate surface of the glass substrate GS larger than the angle of slope of the gate insulating film edge section 16a of the gate insulating film 16 and the first interlayer insulating film edge section 19a of the first interlayer insulating film 19. The first planarization film 20 is more likely to have such a configuration when the first planarization film 20 is used as a mask for patterning the gate insulating film 16 and the first interlayer insulating film 19 in the production of the array board 11b. If the third metal film 21 for forming terminal liens 29 are formed in the layer upper than the first planarization film 20 and the formed third metal film 21 is etched via the photoresist R for forming the terminal lines 29 through the patterning in the production of the array board 11b, the sections of the third metal film 21 overlapping the gate insulating film edge section 16a and the first interlayer insulating film edge section 19a having the larger angle of slope relative to the plate surface of the glass substrate GS are less likely to be removed through the etching. If the sections remain, the adjacent terminal lines 29 may be shorted.

At least parts of the gate insulating film edge section 16a of the gate insulating film 16 and the first interlayer insulating film edge section 19a of the first interlayer insulating film 19 are angled relative to the plate surface of the glass substrate GS with the angle of slope equal to or smaller than 35°. Therefore, the sections of the third metal film 21 that forms the terminal lines 29 at least partially overlapping the gate insulating film edge section 16a and the first interlayer insulating film edge section 19a are more likely to be removed through the etching during the patterning of the terminal lines 29. The residues of the third metal film 21 are less likely to be produced between the sections of the adjacent terminal lines 29 at least partially overlapping the gate insulating film edge section 16a and the first interlayer insulating film edge section 19a. Therefore, the adjacent terminal lines 29 are less likely to be shorted.

The first planarization film 20 includes the first thickness portion 20A and the second thickness portion 20B. The second thickness portion 20B is disposed closer to the input terminals 28 relative to the first thickness portion 20A. The second thickness portion 20B includes the first planarization film edge section 20a and has the thickness smaller than the thickness of the first thickness portion 20A. Because the second thickness portion 20B has the thickness smaller than the thickness of the first thickness portion 20A, in comparison to the configuration in which the first planarization film 20 has the thickness that is equal to the thickness of the first thickness portion 20A for the entire area, the angle of slope of the first planarization film edge section 20a included in the second thickness portion 20B relative to the plate surface of the glass substrate GS is smaller. By patterning the gate insulating film 16 and the first interlayer insulating film 19 using the planarization film 20 as a mask in the production of the array board 11b, the angle of slope of the gate insulating film edge section 16a and the first interlayer insulating film edge section 19a relative to the plate surface of the glass substrate GS can be further reduced. According to the configuration, the angle of slope of the gate insulating film edge section 16a and the first interlayer insulating film edge section 19a can be easily maintain equal to or smaller than 35°. Therefore, further higher reliability can be achieved in the short circuit protection between the adjacent terminal lines 29.

The angle of slope of the gate insulating film edge section 16a of the gate insulating film 16 and the first interlayer insulating film edge section 19a of the first interlayer insulating film 19 relative to the plate surface of the glass substrate GS is equal to or smaller than 35° for the entire areas. Because the angle of slope of the gate insulating film edge section 16a of the gate insulating film 16 and the first interlayer insulating film edge section 19a of the first interlayer insulating film 19 relative to the plate surface of the glass substrate GS is equal to or smaller than 35° for the entire areas, the sections of the third metal film 21 that forms the terminal lines 29 overlapping the entire areas of the gate insulating film edge section 16a and the first interlayer insulating film edge section 19a are more likely to be removed through the etching during the forming of the terminal lines 29 through the patterning. Therefore, the residues of the third metal film 21 are less likely to be produced in the sections between the adjacent terminal lines 29 overlapping the entire areas of the gate insulating film edge section 16a and the first interlayer insulating film edge section 19a. In comparison to the configuration in which parts of the gate insulating film edge section 16a and the first interlayer insulating film edge section 19a are angled relative to the plate surface of the glass substrate GS with the angle of slope equal to or smaller than 35°, further higher reliability can be achieved in the short circuit protection between the adjacent terminal lines.

The liquid crystal panel 11 (the display panel) according to this embodiment includes the array board 11b described above and the CF board 11a (the common board) opposed to the array board 11b. According to the liquid crystal panel 11 having such a configuration, higher reliability can be achieved in short-circuit protection of the array board 11b. Therefore, higher operation reliability can be achieved.

The method of producing the array board 11b in this embodiment includes at least the gate insulating film forming process and the first interlayer insulating film forming process (the first insulating film forming process), the first planarization film forming process (the second insulating film forming process), the first planarization film shaping process (the second insulating film shaping process), the gate insulating film and first interlayer insulating film shaping process (the first interlayer insulating film shaping process), the third metal film forming process (the metal film forming process), the resist forming process, and the terminal line forming process. The gate insulating film forming process and the first interlayer insulating film forming process include forming the gate insulating film 16 and the first interlayer insulating film 19 on the glass substrate GS to cross the boundary between the display area AA and the non-display area NAA. The glass substrate GS includes the display area AA in which images are displayed and the non-display area NAA disposed outside the display area AA to surround the display area AA and in which the input terminals 28 are disposed. The first planarization film forming process includes forming the first planarization film 20 in the layer upper than the gate insulating film 16 and the first interlayer insulating film 19 to cross the boundary between the display area AA and the non-display area NAA. The first planarization film shaping process includes shaping the first planarization film 20 such that the first planarization film edge section 20a, which is the edge section of the first planarization film 20, is angled relative to the plate surface of the glass substrate GS between the input terminals 28 and the display area AA. The gate insulating film and first interlayer insulating film shaping process includes etching the gate insulating film 16 and the first interlayer insulating film 19 via the first planarization film 20 such that the gate insulating film edge section 16a and the first interlayer insulating film edge section 19a, which are the end sections of the gate insulating film 16 and the first interlayer insulating film 19, are angled relative to the plate surface of the glass substrate GS between the input terminals 28 and the display area AA and the angle of slope at least parts of the gate insulating film edge section 16a and the first interlayer insulating film edge section 19a is larger than the angle of slope of the first planarization film edge section 20a and equal to or smaller than 35°. The third metal film forming process includes forming the third metal film 21 in the layer upper than the first planarization film 20 to cross the boundary between the display area AA and the non-display area NAA. The resist forming process includes forming the photoresist R (the resist) in the layer upper than the third metal film 21. The terminal line forming process includes etching the third metal film 21 via the photoresist R to form the terminal lines 29 that are disposed to cross the gate insulating film edge section 16a, the first interlayer insulating film edge section 19a, and the first planarization film edge section 20a and connected to the input terminals 28.

In the gate insulating film forming process and the first interlayer insulating film forming process, the gate insulating film 16 and the first interlayer insulating film 19 are formed on the glass substrate GS to cross the boundary between the display area AA and the non-display area. Then, in the first planarization film forming process, the first planarization film 20 is formed in the layer upper than the gate insulating film and the first interlayer insulating film 19 to cross the boundary between the display area AA and the non-display area NAA. In the first planarization film forming process, the first planarization film 20 is formed such that the first planarization film edge section 20a is angled relative to the plate surface of the glass substrate GS between the input terminals 28 and the display area AA. In the gate insulating film shaping process and the first interlayer insulating film shaping process that are performed afterward, the gate insulating film 16 and the first interlayer insulating film 19 are etched via the first planarization film 20. The angle of slope of the gate insulating film edge section 16a of the gate insulating film 16 and the first interlayer insulating film edge section 19a of the first interlayer insulating film 19 relative to the plate surface of the glass substrate GS is larger than the angle of slope of the first planarization film edge section 20a relative to the plate surface of the glass substrate GS but the angle of slope of at least parts thereof equal to or smaller than 35°. In the third metal film forming process that is performed afterward, the third metal film 21 is formed in the layer upper than the first planarization film 20 to cross the boundary between the display area AA and the non-display area NAA. Then, in the resist forming process, the photoresist R is formed in the layer upper than the third metal film 21. In the terminal line forming process that is performed afterward, the third metal film 21 is etched via the photoresist R and the terminal lines 29 are formed such that the terminal lines 29 are disposed to cross the gate insulating film edge section 16a, the first interlayer insulating film edge section 19a, and the first planarization film edge section 20a and connected to the input terminals 28.

When the third metal film 21 is etched via the photoresist R to form the terminal lines 29 from the third metal film 21 in the terminal line forming process, the sections of the third metal film 21 overlapping the gate insulating film edge section 16a and the first interlayer insulating film edge section 19a having the larger angle of slope relative to the plate surface of the glass substrate GS are less likely to be removed through the etching. If the sections remain, the adjacent terminal lines 29 may be shorted. In the gate insulating film shaping process and the first interlayer insulating film shaping process, at least parts of the gate insulating film edge section 16a of the gate insulating film 16 and the first interlayer insulating film edge section 19a of the first interlayer insulating film 19 are angled relative to the plate surface of the glass substrate GS with the angle of slope equal to or smaller than 35°. Therefore, the sections of the third metal film 21 at least partially overlapping the gate insulating film edge section 16a and the first interlayer insulating film edge section 19a are less likely to be removed through the etching during the formation of the terminal lines 29 from the third metal film 21 in the terminal line forming process. The residues of the third metal film 21 are less likely to be produced in the sections between the adjacent terminal lines 29 at least partially overlapping the gate insulating film edge section 16a and the first interlayer insulating film edge section 19a. Therefore, the adjacent terminal lines 29 are less likely to be shorted.

In the first planarization film forming process, the first planarization film 20 is formed using the photosensitive material. The first planarization film shaping process includes at least the exposing step and the developing step. The exposing step includes exposing the first planarization film 20 using the grey tone mask GM as a photomask. The grey tone mask GM includes the transmissive areas TA and the semitransmissive area HTA. In the exposing step, the grey tone mask GM is disposed such that at least the semitransmissive area HTA is positioned to overlap the section of the first planarization film 20 at which the first planarization film edge section 20a is to be formed. The developing step includes developing the first planarization film 20.

In the first planarization film forming process, the first planarization film 20 is formed using the photosensitive material. In the exposing step included in the first planarization film shaping process, the first planarization film 20 is exposed using the grey tone mask GM that includes the transmissive areas TA and the semitransmissive area HTA. In the developing step that is performed afterward, the first planarization film 20 is developed. Through the processes, the first planarization film 20 that includes the first planarization film edge section 20a is formed. The grey tone mask GM used in the exposing step is disposed such that at least the semitransmissive area HTA is positioned to overlap the section of the first planarization film 20 at which the first planarization film edge section 20a is to be formed. Therefore, the exposed and developed first planarization film 20 includes the section including the first planarization film edge section 20a in the thickness smaller than the thickness of other sections. When the gate insulating film 16 and the first interlayer insulating film 19 are etched via the first planarization film 20 in the gate insulating film shaping process and the first interlayer insulating film shaping process that are performed afterward, the angle of slope of the gate insulating film edge section 16a and the first interlayer insulating film edge section 19a relative to the plate surface of the glass substrate GS becomes further smaller. Therefore, the angle of slope of the gate insulating film edge section 16a and the first interlayer insulating film edge section 19a can be easily maintained at 35° or smaller. Further higher reliability can be achieved in the short circuit protection between the adjacent terminal lines.

### Second Embodiment

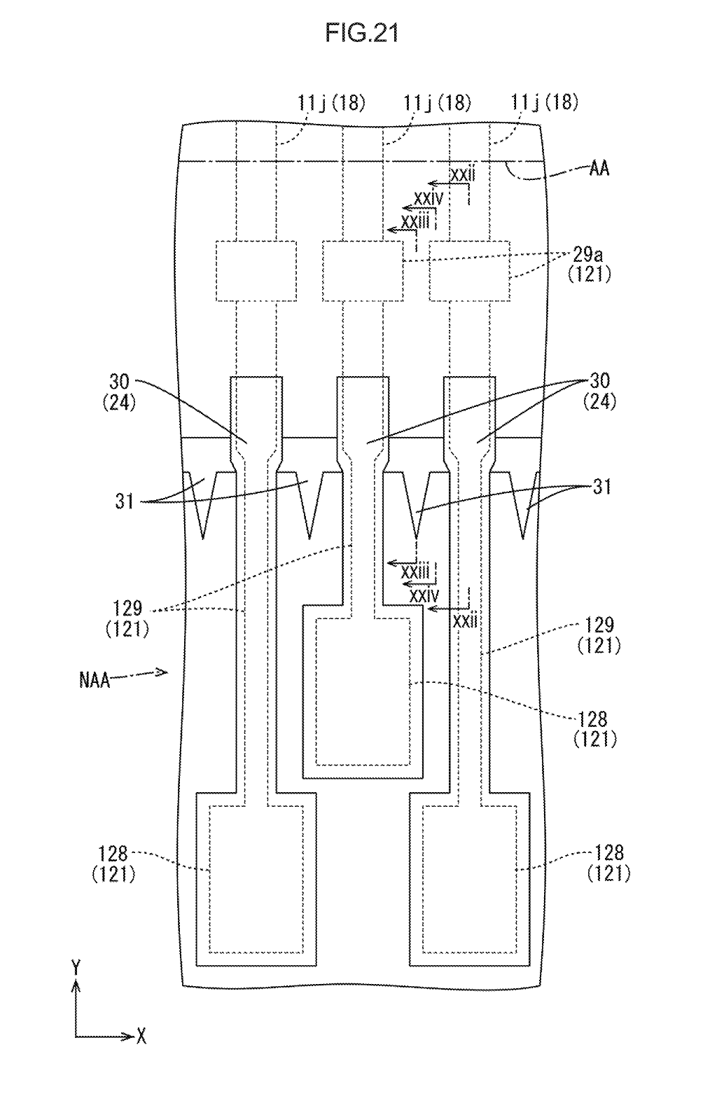

A second embodiment of the present invention will be described with reference to FIGS. 21 to 25. The second embodiment includes a gate insulating film 116, a first interlayer insulating film 119, and a first planarization film 120 that include projections 31. Configurations, functions, and effects similar to those of the first embodiment will not be described.

As illustrated in FIG. 21, the gate insulating film 116, the first interlayer insulating film 119, and the first planarization film 120 in the array board 111b according to this embodiment include the projections 31. The projections 31 are disposed at a gate insulating film edge section 116a, a first interlayer insulating film edge section 119a, and a first planarization film edge section 120a between terminals lines 129 that are adjacent to each other with respect to the X-axis direction. The projections 31 project toward input terminals 128 along the Y-axis direction. Each projection 31 is disposed at the middle between the terminal lines 129 that are adjacent to each other with respect to the X-axis direction. A distance between the projection 31 and the adjacent terminal line 129 on the left in FIG. 21 is about equal to a distance between the projection 31 and the adjacent terminal line 129 on the right in FIG. 21. The projections 31 and the terminal lines 129 are alternately arranged at intervals along the X-axis direction. Each projection 31 has a tapered two-dimensional shape with a width that decreases as a distance from a base of projection in the Y-axis direction toward a distal end increases (as closer to the input terminals 128). Specifically, each projection 31 has a triangular shape in a plan view. In this embodiment, a thickness of the first planarization film 120 is about equal to the thickness of the first thickness portion 20A in the first embodiment and substantially constant for an entire area to form the projections 31.

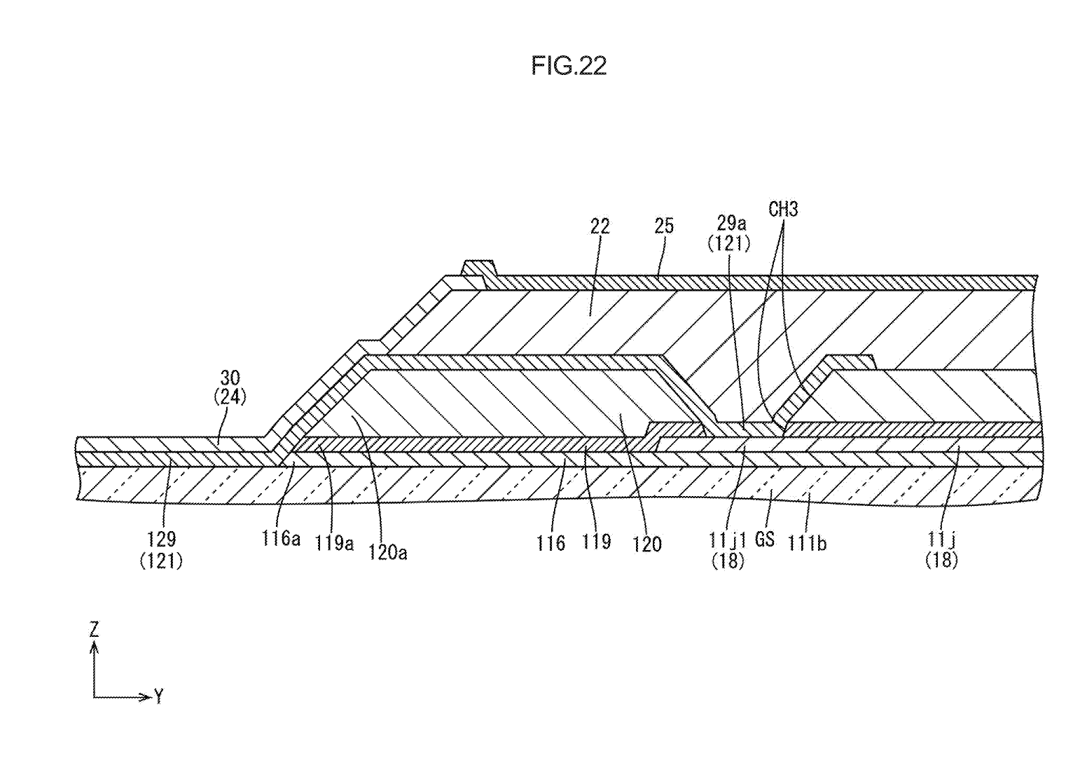

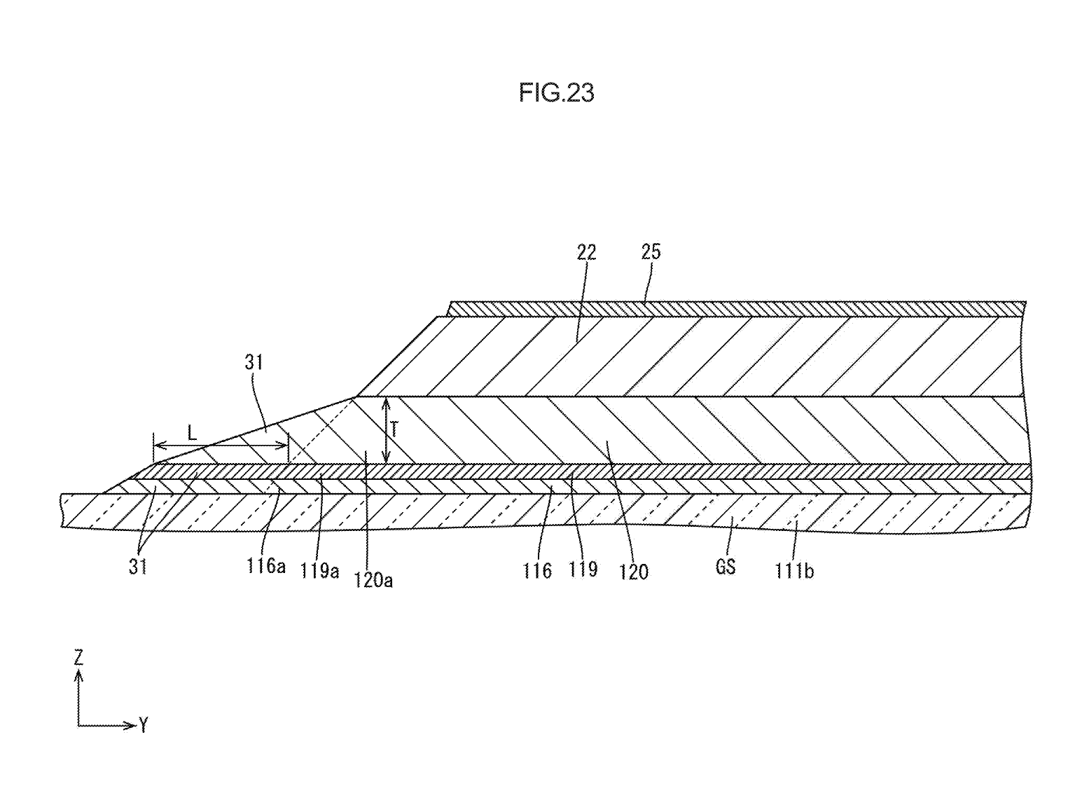

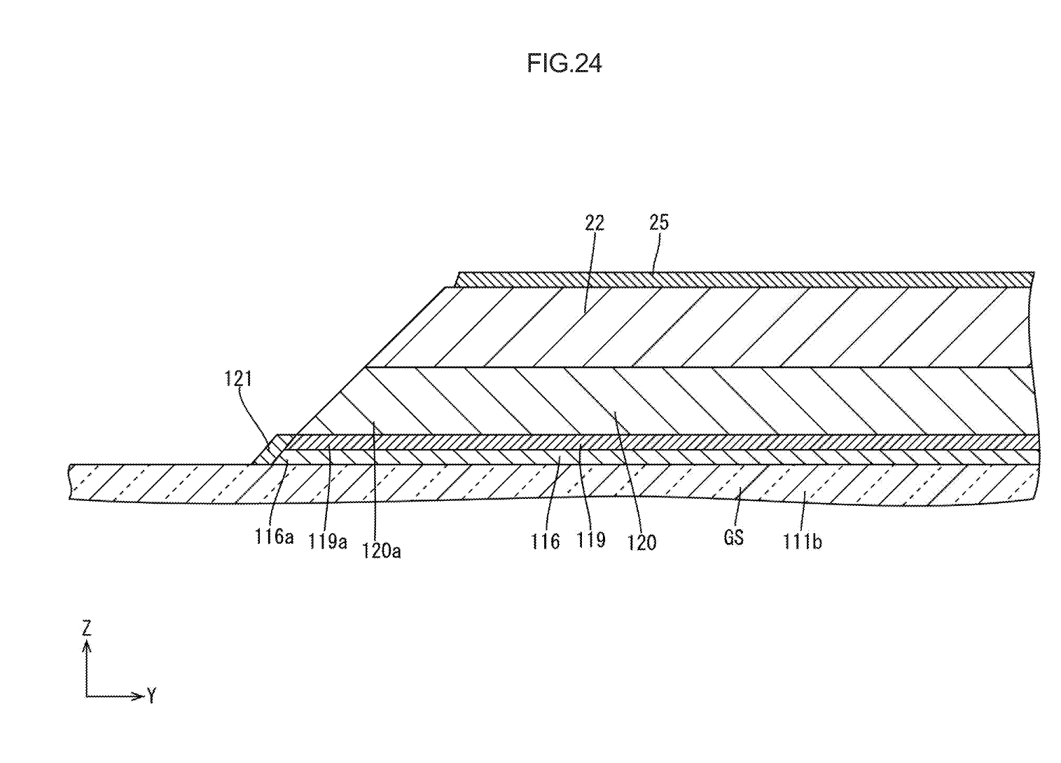

Because each projection 31 narrows toward the distal end, as illustrated in FIGS. 22 to 24, an angle of slope of each projection 31 relative to the plate surface of the glass substrate GS is smaller than an angle of slope of sections of the gate insulating film edge section 116a, the first interlayer insulating film edge section 119a, and the first planarization film edge section 120a at which the projections 31 are not formed relative to the plate surface of the glass substrate GS and equal to or smaller than 35° (but larger than 0°). The first planarization film 120 is patterned prior to the gate insulating film 116 and the first interlayer insulating film 119 in the production of the array board 111b. The angle of slope the sections of the first planarization film edge section 120a of the planarization film 120 at which the projections 31 are formed (FIG. 23) relative to the plate surface of the glass substrate GS is smaller than the angle of slope of the sections of the first planarization film edge section 120a at which the projections 31 are not formed (FIGS. 22 and 24) relative to the plate surface of the glass substrate GS. The gate insulating film 116 and the first interlayer insulating film 119 are patterned using the first planarization film 120 as a mask. An angle of slope of sections of the gate insulating film edge section 116a and the first interlayer insulating film edge section 119a at which the projections are formed (FIG. 23) relative to the plate surface of the glass substrate GS is smaller than an angle of slope of sections of the gate insulating film edge section 116a and the first interlayer insulating film edge section 119a at which the projections 31 relative to the plate surface of the glass substrate GS are not formed (FIGS. 22 and 24). Namely, the angle can be easily set equal to or smaller than 35°. As illustrated in FIG. 23, when the third metal film 121 that forms the terminal lines 129 is patterned, the residues of the third metal film 121 are less likely to be produced at least in the sections of the gate insulating film edge section 116a and the first interlayer insulating film edge section 119a at which the projections 31 are formed. If the angle of slope of the sections at which the projections 31 are not formed relative to the plate surface of the glass substrate GS is larger than 35° and the residues of the third metal film 121 are produced in the sections at which the projections 31 are not formed, the residues of the third metal film 121 are less likely to be produced in the sections at which the projections 31 are formed as illustrated in FIG. 23 because the angle of slope of the sections at which the projections are formed relative to the plate surface of the glass substrate GS is equal to or smaller than 35°. Therefore, the adjacent terminal lines 129 are less likely to be bridged by the residues of the third metal film 121. Sufficiently high reliability can be achieved in short circuit protection between the adjacent terminal lines 129. Furthermore, creepage distances between the adjacent terminal lines 129 at the gate insulating film edge section 116a, the first interlayer insulating film edge section 119a, and the first planarization film edge section 120a are increased by dimensions of the projections 31. Therefore, even if the residues of the third metal film 121 that forms the terminal lines 129 are produced around the gate insulating film edge section 116a, the first interlayer insulating film edge section 119a, and the first planarization film edge section 120a, the adjacent terminal lines 129 are less likely to be bridged by the residues of the third metal film 121.

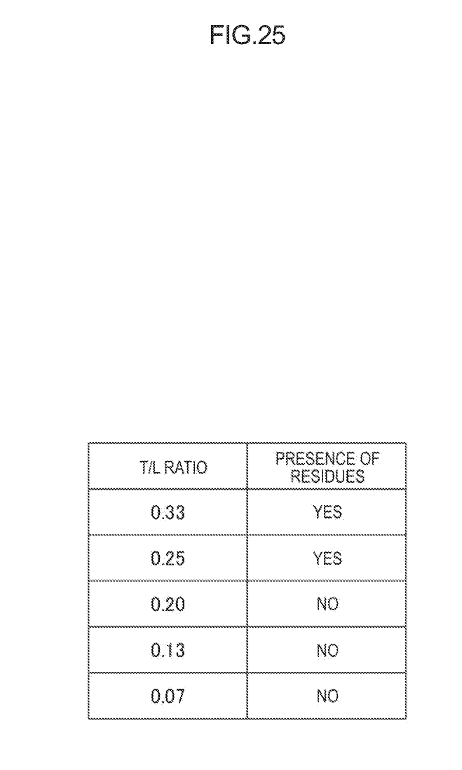

More preferably, as illustrated in FIGS. 21 and 23, each projection 31 is defined such that a T/L ratio is larger than 0 and equal to or smaller than 0.2 where L is a dimension between the base of projection and the distal end, T is a thickness of the first planarization film edge section 120a, and T/L is calculated by dividing the thickness T by the dimension L. To observe how presence of the residues of the third metal film 121 varies in the sections overlapping the projections 31 as the T/L ratio is altered, comparative experiment 2 was conducted. In comparative experiment 2, comparative example 1 having the T/L ratio of 0.33, comparative example 2 having the T/L ratio of 0.25, embodiment 1 having the T/L ratio of 0.2, embodiment 2 having the T/L ratio of 0.13, and embodiment 3 having the T/L ratio of 0.07 were used. In comparative experiment 2, whether or not the residues of the third metal film 121 were present at the sections overlapping the projections 31 after the forming and the patterning of the third metal film 121 in each array board 111b in each comparative example or embodiment was observed. The results are provided in a table in FIG. 25. In comparative examples 1 and 2, the residues of the third metal film 121 were observed. In embodiments 1 through 3, the residues of the third metal film 121 were not observed. The results suggest that the residues of the third metal film 121 may be produced at the positions overlapping the projections 31 if the T/L ratio is larger than 0.2 and thus the adjacent terminal lines 129 may be shorted. If the T/L ratio is larger than 0 and equal to or smaller than 0.2, the residues of the third metal film 121 are less likely to be produced at the positions overlapping the projections 31 and sufficiently high reliability can be achieved in the short circuit protection between the adjacent terminal lines 129.

As described above, according to this embodiment, the projections 31 are disposed between the adjacent terminal lines 129 at the gate insulating film edge section 116a of the gate insulating film 116 and the first interlayer insulating film edge section 119a of the first interlayer insulating film 119. The projections 31 project toward the input terminals 128. At the gate insulating film edge section 116a and the first interlayer insulating film edge section 119a, at least the projections 31 are angled relative to the plate surface of the glass substrate GS. The angle of slope relative to the plate surface of the glass substrate GS is equal to or smaller than 35°. Because at least the angle of slope of the projections 31 relative to the plate surface of the glass substrate GS at the gate insulating film edge section 116a and the first interlayer insulating film edge section 119a is equal to or smaller than 35°, the sections of the third metal film 121 that forms the terminal lines 129 overlapping at least the projections 31 at the gate insulating film edge section 116a and the first interlayer insulating film edge section 119a are more likely to be removed through the etching. Therefore, the adjacent terminal lines 129 are less likely to be shorted. Furthermore, the creepage distances between the adjacent terminal lines 129 at the gate insulating film edge section 116a and the first interlayer insulating film edge section 119a are increased by dimensions of the projections 31. Therefore, even if the residues of the third metal film 121 that forms the terminal lines 129 are produced in the sections of the gate insulating film edge section 116a and the first interlayer insulating film edge section 119a at which the projections 31 are not formed, the adjacent terminal lines 129 are less likely to be bridged by the residues of the third metal film 121.

Each projection 31 is defined such that the T/L ratio, which is a division of the dimension L between the base of projection and the distal end by the thickness T of the first planarization film edge section 120a, is equal to or smaller than 0.2. If the T/L ratio, which is a division of the dimension L between the base of projection and the distal end by the thickness T of the first planarization film edge section 120a is larger than 0.2, the residues of the third metal film 121 that forms the terminal lines 129 are more likely to be produced around the gate insulating film edge section 116a and the first interlayer insulating film edge section 119a. Therefore, the adjacent terminal lines 129 are more likely to be shorted. By setting the T/L ratio equal to or smaller than 0.2, the residues of the third metal film 121 are less likely to be produced around the gate insulating film edge section 116a and the first interlayer insulating film edge section 119a. Therefore, the adjacent terminal lines 129 are less likely to be shorted.

### Third Embodiment

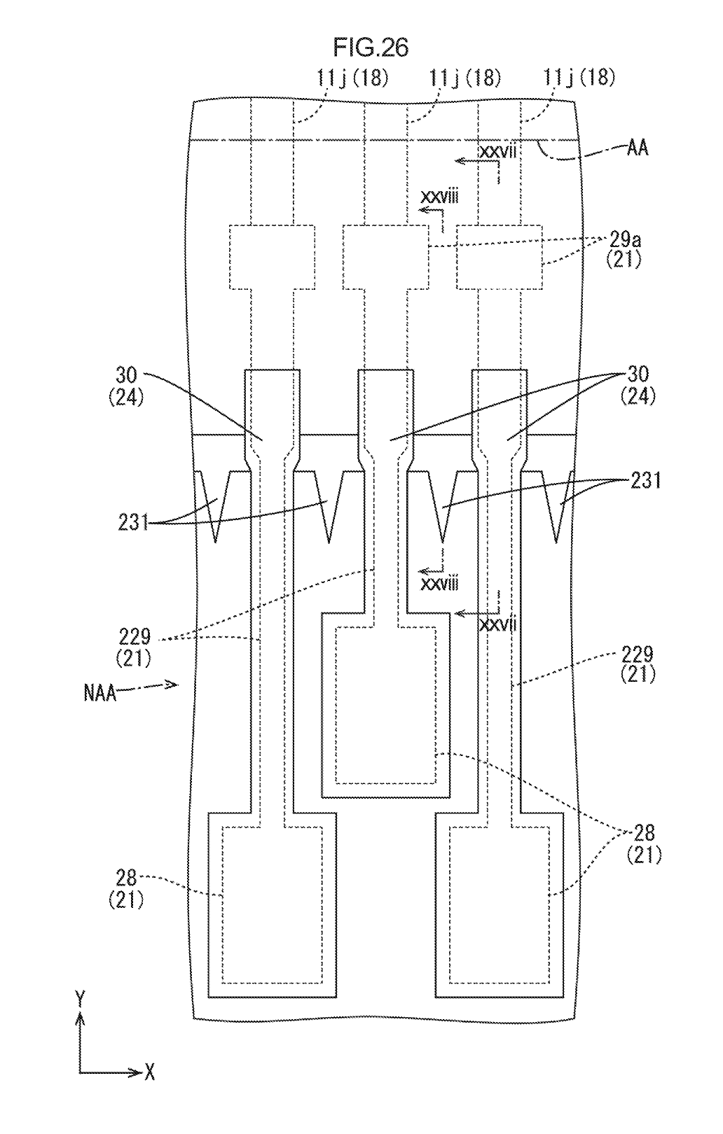

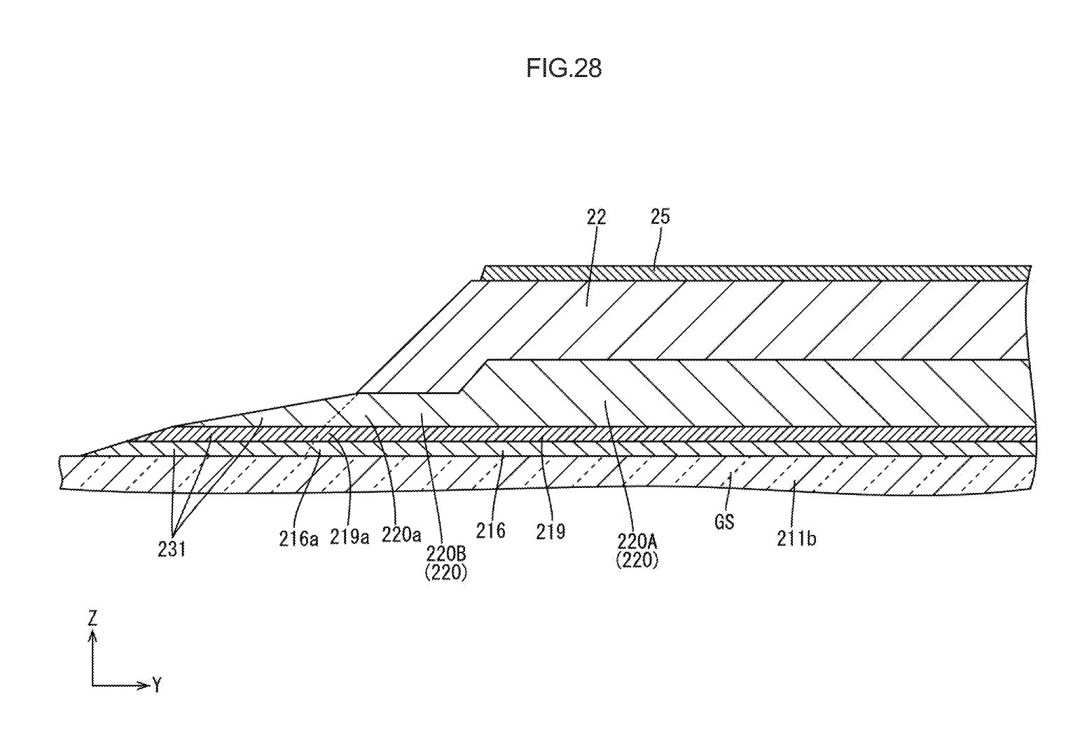

A third embodiment of the present invention will be described with reference to FIGS. 26 to 28. The third embodiment is a combination of the first embodiment and the second embodiment. Configurations, functions, and effects similar to those of the first and the second embodiments will not be described.

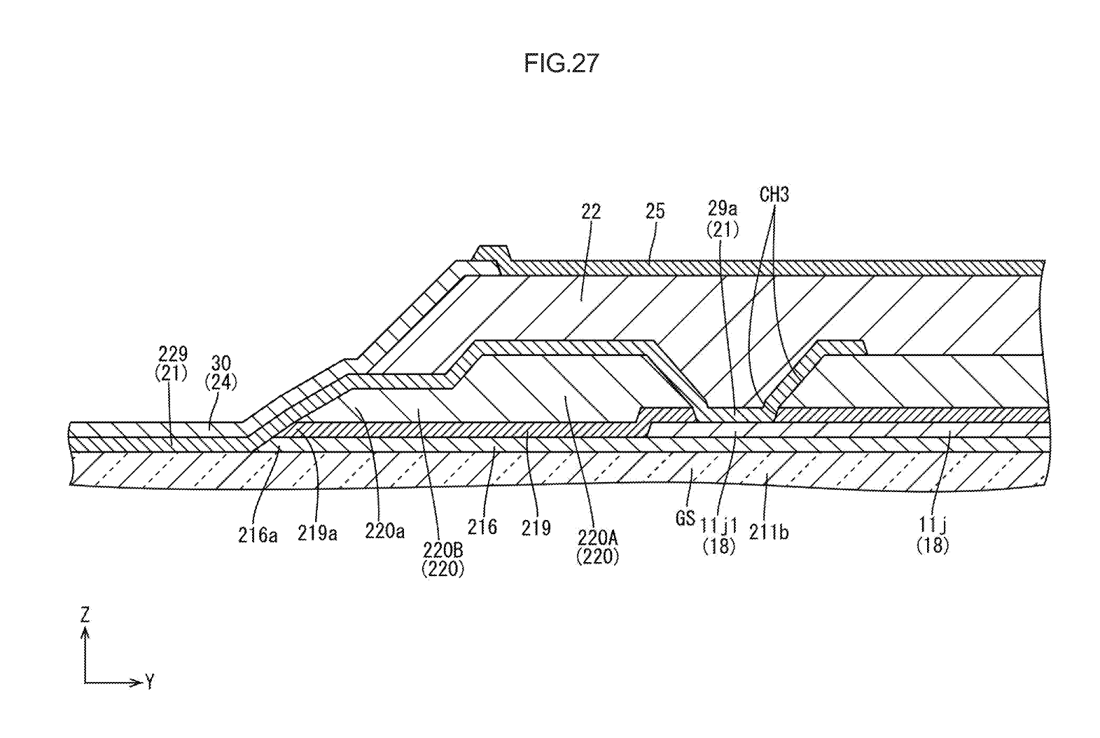

As illustrated in FIGS. 26 and 27, an array board 211b in this embodiment includes a first planarization film 220, a gate insulating film 216, and a first interlayer insulating film 219. The first planarization film 220 includes a first thickness portion 220A and a second thickness portion 220B. The second thickness portion 220B has a thickness smaller than the thickness of the first thickness portion 220A and includes a first planarization film edge section 220a. Furthermore, the gate insulating film 216, the first interlayer insulating film 219, and the first planarization film 220 includes projections 231. According to the configuration, an angle of slope of a gate insulating film edge section 216a of the gate insulating film 216 and a first interlayer insulating film edge section 219a of the first interlayer insulating film 219 relative to the plate surface of the glass substrate GS can be larger than 0° and equal to or smaller than 35° for entire areas. Furthermore, an angle of slope of sections of the gate insulating film edge section 216a and the first interlayer insulating film edge section 219a at which the projections 231 are formed can be further reduced in comparison to that in the second embodiment. According to the configuration, further higher reliability can be achieved in short circuit protection between the adjacent terminal lines 229.

### Fourth Embodiment

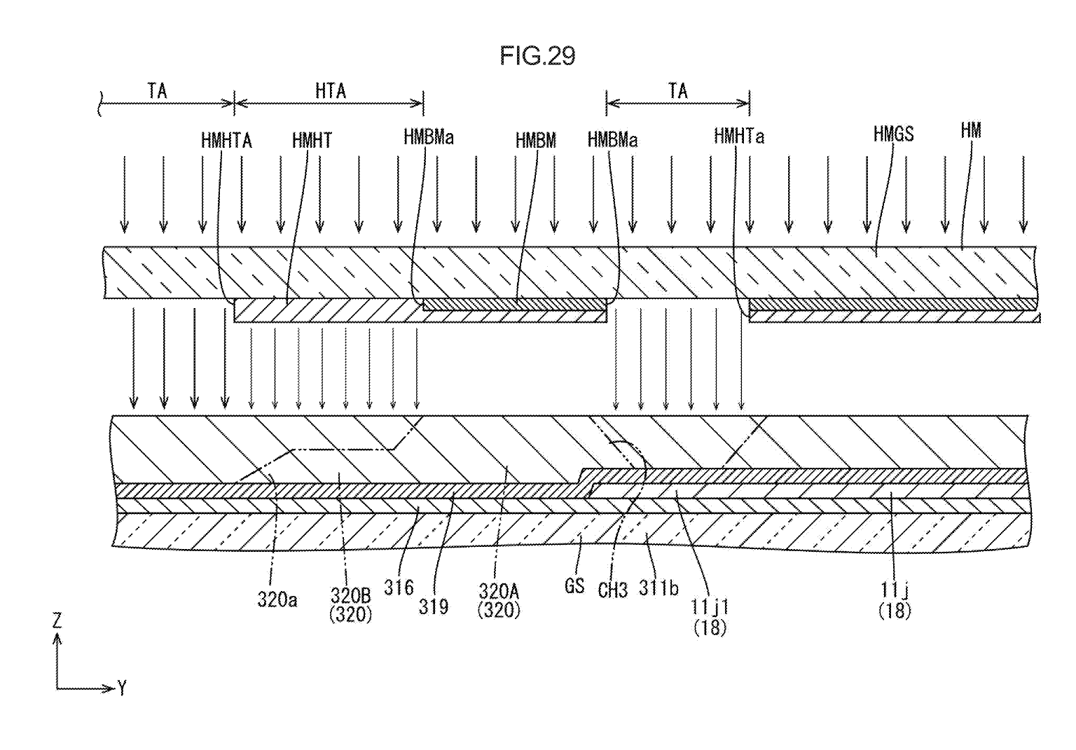

A fourth embodiment will be described with reference to FIG. 29. The fourth embodiment includes an exposing step in which a halftone mask HM is used as a photomask instead of the photomask used in the first embodiment. Configurations, functions, and effects similar to those of the first embodiment will not be described.

A method of producing an array board 311b according to this embodiment includes a first planarization film forming process. The first planarization film forming process includes a film forming step in which a first planarization film 320 is formed from a positive-type photosensitive material and an exposing step in which the halftone mask HM is used as a photomask. As illustrated in FIG. 29, the halftone mask HM includes a transparent glass base HMGS, a light blocking film HMBM, and a semitransmissive film HMHT. The light blocking film HMBM is formed on a plate surface of the glass base HMGS to block light from an exposing light source. The semitransmissive film HMHT pass the light from the exposing light source with a predefined transmissivity. The transmissivity of the light blocking film HMBM to pass the light is about 0%. The light blocking film HMBM includes holes HMBMa at a position at which the first planarization film 320 in the solid pattern does not overlap the first planarization film 320 after the patterning and at a position at which the second thickness portion 320B is to be formed. The semitransmissive film HMHT is formed on the light blocking film HMBM on an opposite side from a glass base HMGS side. The semitransmissive film HMHT has transmissivity of about 10% to 70% to pass the light. The semitransmissive film HMHT includes a hole HMHTa at a position at which the first planarization film 320 in the solid pattern does not overlap the first planarization film 320 after the patterning. Namely, in a section of the glass base HMGS of the halftone mask HM overlapping the section of the first planarization film 320 in which the second thickness portion 320B is to be formed, the light blocking film HMBM is not formed but the semitransmissive film HMHT is formed. This section is referred to as a semitransmissive area HTA having the transmissivity of about 10% to 70% to pass the light. The half transmissive area HTA is an area of the hole HMBMa of the light blocking film HMBM not overlapping the hole HMHTa of the semitransmissive film HMHT. The hole HMHTa of the semitransmissive film HMHT is referred to as a transmissive areas TA having transmissivity of about 100% to pass the light.

In the exposing step that uses the halftone mask HM having such a configuration, when an ultraviolet ray, which is the light from the exposing light source, is applied to the first planarization film 320 in the solid pattern via the halftone mask HM, an amount of applied light is larger in the section of the first planarization film 320 overlapping the hole HMHTa (the transmissive areas TA) of the semitransmissive film HMHT and an amount of applied light is smaller in the section of the hole HMBMa of the light blocking film HMBM not overlapping the hole HMHTa of the semitransmissive film HMHT (the semitransmissive area HTA). When the developing step is performed afterward, the thickness of the second thickness section 320B of the first planarization film 320 is smaller and the thickness of the first thick section 320A of the first planarization film 320 is larger. In a single exposing step, the first planarization film 320 including the sections with different thicknesses can be formed. Therefore, production time can be reduced.

As described above, according to this embodiment, the first planarization film 320 is formed using the photosensitive material in the first planarization film forming process. The first planarization film forming process includes the exposing step and the developing step. The exposing step includes exposing the first planarization film 320 using the halftone mask HM that includes the transmissive areas TA and the semitransmissive area HTA as a photomask. The halftone mask HM is disposed such that at least the semitransmissive area HTA is positioned to overlap the section of the first planarization film 310 at which a first planarization film edge section 320a is to be formed. The developing step includes developing the first planarization film 320.

In the first planarization film forming process, the first planarization film 320 is formed using the photosensitive material. In the exposing step includes in the first planarization film shaping process, the first planarization film 320 is exposed using the halftone mask HM that includes the transmissive areas TA and the semitransmissive area HTA. Then, the first planarization film 320 is developed in the developing step. Through the steps the first planarization film 320 that includes the first planarization film edge section 320a is formed. The halftone mask HM used in the exposing step is disposed such that at least the semitransmissive area HTA is positioned to overlap the section at which the first planarization film edge section 320a is formed. The section of the exposed and developed first planarization film 320 including the first planarization film edge section 320a has the thickness smaller than the thickness of other sections. In the gate insulating film shaping process and the first interlayer insulating film shaping process that are performed afterward, when the gate insulating film 316 and the first interlayer insulating film 319 are etched via the first planarization film 320, the angle of slope of the gate insulating film edge section and the first interlayer insulating film edge section relative to the plate surface of the glass substrate GS becomes further smaller. Therefore, the angle of slope of the gate insulating film edge section and the first interlayer insulating film edge section can be easily maintained larger than 0° and equal to or smaller than 35°. Further higher reliability can be achieved in the short circuit protection between the adjacent terminal lines.

### Other Embodiments

The present invention is not limited to the above embodiments described in the above sections and the drawings. For example, the following embodiments may be included in technical scopes of the present invention.

(1) In each of the above embodiment sections, the terminal lines are formed from the third metal film that also forms the TFT connecting portions. However, the terminal lines may be formed from the fourth metal film that also forms the position detection lines.

(2) In each of the above embodiments, the input terminals are formed from the third metal films that also forms the TFT connecting portions. However, the input terminals may be formed from the fourth metal film that also forms the position detection lines, the second metal film that also forms the source lines, or the first metal film that also forms the gate lines.

(3) In each of the above embodiments, the terminal lines are connected to the source lines. However, the terminal lines may be connected to the lines other than the source lines such as the gate lines and the position detection lines.

(4) In each of the above embodiments, the first interlayer insulating film is disposed in the layer lower than the first planarization film. However, the first interlayer insulating film may be omitted.

(5) In each of the second and the third embodiments, each projection has the triangular shape in the plan view. However, each projection may have a shape other than the triangular shape in the plan view such as a trapezoidal shape, a circular shape (a semicircular shape), an oval shape (a semi-oval shape), a quadrilateral shape, and a polygonal shape having five or more corners.

(6) As a modification of the first and the third embodiments, a negative-type photosensitive material may be used for the first planarization film. In this modification, the transmissive area and the light blocking area of the halftone mask or the gray tone mask may be disposed the other way around relative to those in the first and the third embodiments.

(7) In each of the above embodiments, the position input is performed by the finger of the user. However, the position input may be performed by a position input device other than the finger such as a stylus.

(8) In each of the above embodiments, the position detection electrodes and the common electrode are unified. However, the position detection electrode may be provided separately from the common electrode.

(9) In each of the above embodiment sections, the in-cell type liquid crystal panel including the touchscreen pattern (e.g., the position detection electrodes and the position detection lines) is embedded in the liquid crystal panel is described. However, the liquid crystal panel may be an on-cell type display panel or an out-cell type display panel. Specifically, the out-cell type liquid crystal panel may not have the position detection function (the touchscreen pattern).

(10) In each of the above embodiment sections, the liquid crystal display device having the position detection function (the touchscreen pattern). However, the present invention may be applied to liquid crystal display devices that do not have the position detection function.

(11) In each of the above embodiments, the liquid crystal panel has the rectangular shape in the plan view. However, the present invention may be applied to liquid crystal panels having quadrilateral shapes, circular shapes, and overall shapes in the plan view.

(12) In each of the above embodiments, the driver is COG-mounted on the array board of the liquid crystal panel. However, the driver may be chip-on-film (COF) mounted on the liquid crystal panel flexible circuit board.

(13) In each of the above embodiments, the semiconductor film of the channels of the TFT is made of the oxide semiconductor material. Other than that, continuous grain (CG) silicon, which is one kind of polysilicon, or amorphous silicon may be used as a material for the semiconductor film.

(14) In each of the above embodiment sections, the liquid crystal panel that is configured to operate in FFS mode is described. However, the present invention may be applied to liquid crystal panels that are configured to operate in other modes such as in-plane switching (IPS) mode and vertical alignment (VA) mode.

(15) In each of the above embodiment sections, the color filters of the liquid crystal panel have the three-color configuration of red, green, and blue. However, the present invention may be applied to color filters have a four-color configuration including yellow color portions in addition to the red, the green, and the blue color portions.

(16) In each of the above embodiment sections, the liquid crystal panel that includes the liquid crystal layer that is sandwiched between the boards is described. However, the present invention may be applied to a display panel that includes functional organic molecules other than the liquid crystals sandwiched between boards.

(17) In each of the above embodiments, the TFTs are used as the switching components of the liquid crystal panel. However, the present invention may be applied to a liquid crystal panel that includes switching components other than TFTs (e.g., thin film diodes (TFD)). The present invention may be applied to a liquid crystal panel that is configured to display black-and-white images other than the liquid crystal panel that is configured to display color images and a method of producing the liquid crystal panel.

(18) In each of the above embodiment sections, the liquid crystal panel is described. However, the present invention may be applied to other types of display panels (e.g., plasma display panels (PDPs), organic EL panels, electrophoretic display panels (EPDs), and micro electro mechanical systems (MEMS)).

(19) In the first embodiment section, the results of comparative experiment 1 in which the embodiments having the angles of slope of the gate insulating film edge sections and the first interlayer insulating film edge sections set to 2°, 5°, 13°, and 35°, respectively, are used are described. However, the angle of slope of the gate insulating film edge sections and the first interlayer insulating film edge sections may be set in a range from 0° to 2°, from 2° to 5°, from 5° to 13°, or from 13° to 35°. In such a case, the same result, that is, “no residues are present” is more likely to be obtained. Therefore, the angle of slope of the gate insulating film edge section and the first interlayer insulating film edge section may be set in any of the above ranges.

(20) In the second embodiment section, the results of comparative experiment 2 in which the embodiments having the T/L ratios set to 0.2, 0.13, and 0.07, respectively, are used are described. However, the T/L ratio may be set in a range from 0.13 to 0.2, from 0.07 to 0.13, or from 0 to 0.07. In such a case, the same result, that is, “no residues are present” is more likely to be obtained. Therefore, the T/L ratio may be set in any of the above ranges.

### EXPLANATION OF SYMBOLS

11: Liquid crystal panel (Display panel)
11a: CF board (Common board)
11b, 111b, 211b, 311b: Array board (Display board)
16, 116, 216: Gate insulating film (First insulating film)
16a, 116a, 216a: Gate insulating film edge section (First insulating film edge section)
19, 119, 219: First interlayer insulating film (First insulating film)
19a, 119a, 219a: First interlayer insulating film edge section (First insulating film edge section)
20, 120, 220, 320: First planarization film (Second insulating film)
20a, 120a, 220a, 320a: First planarization film edge section (Second insulating film edge section)
20A, 220A, 320A: First thickness portion
20B, 220B, 320B: Second thickness portion
21, 121: Third metal film (Metal film)
28, 128: Input terminal (Terminal)
29, 129, 229: Terminal line
31, 231: Projection
AA: Display area
GM: Grey tone mask
GS: Glass substrate (Substrate)
HM: Halftone mask
HTA: Semitransmissive area
L: Dimension
NAA: Non-display area
R: Photoresist (Resist)
T: Thickness
TA: Transmissive area

1. A display board comprising:
a board including a display area in which an image can be displayed and a non-display area disposed outside the display area to surround the display area;
a plurality of terminals disposed in the non-display area;
a first insulating film disposed to cross a boundary between the display area and the non-display area and including a first insulating film edge section disposed between the plurality of terminals and the display area, the first insulating film edge section being an edge section of the first insulating film and angled relative to a plate surface of the board with an angle of slope of at least a part of the first insulating film edge section equal to or smaller than 35°;
a second insulating film disposed in a layer upper than the first insulating film to cross the boundary between the display area and the non-display area and including a second insulating film edge section disposed between the plurality of terminals and the display area, the second insulating film edge section being an edge section of the second insulating film and angled relative to the plate surface of the board with an angle of slope smaller than the angle of slope of the first insulating film edge section; and
a plurality of terminal lines disposed in a layer upper than the second insulating film at least in the non-display area, the plurality of terminal lines being formed from a metal film, disposed to cross the first insulating film edge section and the second insulating film edge section, and connected to the plurality of terminals.

2. The display board according to claim 1, wherein the second insulating film includes a first thickness portion and a second thickness portion with a thickness smaller than a thickness of the first thickness portion, the second thickness portion being disposed closer to the plurality of terminal relative to the first thickness portion and including the second insulating film edge section.

3. The display board according to claim 1, wherein the angle of slope of the first insulating film edge section of the first insulating film relative to the plate surface of the board is equal to or smaller than 35° for an entire area.

4. The display board according to claim 1, wherein
the first insulating film includes a projection at the first insulating film edge section,
the projection is disposed between the adjacent terminal lines to project toward the plurality of terminals, and
At least the projection at the first insulating film edge section is angled relative to the plate surface of the board with an angle of slope equal to or smaller than 35°.

5. The display board according to claim 4, wherein the projection has a dimension between a base of projection and a distal end defined such that a ratio calculated by dividing the dimension by a thickness of the second insulating film edge section is equal to or smaller than 0.2.

6. A display device comprising:
the display board according to claim 1; and
a common board disposed opposite the display board.

7. A method of producing a display board comprising at least:
a first insulating film forming process including forming a first insulating film on a board including a display area in which an image can be displayed, a non-display area disposed outside the display area to surround the display area, and a plurality of terminals disposed in the non-display area to cross a boundary between the display area and the non-display area;
a second insulating film forming process including forming a second insulating film in a layer upper than the first insulating film to cross the boundary between the display area and the non-display area;
a second insulating film shaping process including shaping the second insulating film such that a second insulating film edge section that is an edge section of the second insulating film is angled relative to a plate surface of the board between the plurality of terminals and the display area;
a first insulating film shaping process including etching the first insulating film via the second insulating film such that a first insulating film edge section that is an edge section of the first insulating film is angled relative to the plate surface of the board with an angle of slope of at least a part of the first insulating film edge section larger than the angle of slope of the second insulating film edge section and equal to or smaller than 35° between the plurality of terminals and the display area;
a metal film forming process including forming a metal film in a layer upper than the second insulating film to cross the boundary between the display area and the non-display area;
a resist forming process including forming a resist in a layer upper than the metal film; and
a terminal line forming process including etching the metal film via the resist to form a plurality of terminal lines such that the plurality of terminal lines are disposed to cross the first insulating film edge section and the second insulating film edge section and connected to the plurality of terminals.

8. The method of producing a display board according to claim 7, wherein
the second insulating film forming process includes forming the second insulating film using a photosensitive material, and
the second insulating film shaping process includes at least:
an exposing step including exposing the second insulating film using a halftone mask or a grey tone mask including a transmissive area and a semitransmissive area as a photomask, the halftone mask or the grey tone mask being positioned such that at least the semitransmissive area overlaps a section of the second insulating film at which the second insulating film edge section is to be formed; and
a developing step includes developing the second insulating film.
